(19) United States
(12) Patent Application Publication
(10) Pub. No.: US 2025/0254858 A1
(43) Pub. Date: Aug. 7, 2025

(54) SEMICONDUCTOR MEMORY DEVICE INCLUDING LOWER ELECTRODE WITH BOWING AREA

(71) Applicant: SAMSUNG ELECTRONICS CO., LTD., SUWON-SI (KR)

(72) Inventors: Yang Doo KIM, Suwon-si (KR); Sang Wuk PARK, Suwon-si (KR); Min Kyu SUH, Suwon-si (KR); Geon Yeop LEE, Suwon-si (KR); Do Keun LEE, Suwon-si (KR); Ji Hye LEE, Suwon-si (KR); Je-Woo HAN, Suwon-si (KR)

(21) Appl. No.: 18/909,066

(22) Filed: Oct. 8, 2024

(30) Foreign Application Priority Data
Feb. 5, 2024 (KR) 10-2024-0017137

(51) Int. Cl. H10B 12/00

(52) U.S. Cl. CPC H10B 12/315; H10B 12/482; H10B 12/485; H10B 12/488

(57) ABSTRACT

A semiconductor memory device includes a conductive pattern. A lower electrode is connected to the conductive pattern. A first lower electrode support is spaced apart from the conductive pattern. The first lower electrode support is in contact with a sidewall of the lower electrode, and includes an upper surface and a bottom surface. The bottom surface of the first lower electrode support faces the conductive pattern. A capacitor dielectric film is disposed on the lower electrode and the first lower electrode support. An upper electrode is disposed on the capacitor dielectric film. The lower electrode includes at least one first bowing area. A width of the lower electrode in the first bowing area of the lower electrode increases and then decreases away from the conductive pattern. The first bowing area of the lower electrode is disposed between the conductive pattern and the first lower electrode support.

### CROSS-REFERENCE TO RELATED APPLICATION

This application claims priority under 35 U.S.C. § 119 to Korean Patent Application No. 10-2024-0017137 filed on Feb. 5, 2024 in the Korean Intellectual Property Office the contents of which in its entirety are herein incorporated by reference.

### TECHNICAL FIELD

The present disclosure relates to a semiconductor memory device, and more specifically, a semiconductor memory device that includes a lower electrode with a bowing area.

### DISCUSSION OF THE RELATED ART

Recently, as semiconductor devices have become larger in capacity and more highly integrated, a design rule thereof specifies smaller minimum dimensions, maximum dimensions and spacing. For example, this trend is occurring in dynamic random-access memory (DRAM), which is an example of a memory semiconductor device. In order for the DRAM device to operate, each cell requires a certain level of capacitance.

An increase in the capacitance increases the amount of charge stored in the capacitor, thereby improving refresh characteristics of the semiconductor device. The improved refresh characteristics of the semiconductor device may improve a yield of the semiconductor device.

However, it may be difficult to achieve higher capacitances when manufacturing semiconductor devices with smaller dimensions. To increase the capacitance, research is being done on using a dielectric film with a high dielectric constant in the capacitor or increasing a contact area between a lower electrode of the capacitor and the dielectric film.

### SUMMARY

A semiconductor memory device includes a conductive pattern disposed on a substrate, a lower electrode connected to the conductive pattern, and extending primarily in a first direction, a first lower electrode support spaced apart from the conductive pattern in the first direction, wherein the first lower electrode support is in contact with a sidewall of the lower electrode, and includes an upper surface and a bottom surface opposite to each other in the first direction, wherein the bottom surface of the first lower electrode support faces the conductive pattern, a capacitor dielectric film disposed on the lower electrode and the first lower electrode support, and an upper electrode disposed on the capacitor dielectric film, wherein the lower electrode includes at least one first bowing area, wherein a width in a second direction of the lower electrode in the first bowing area of the lower electrode increases and then decreases in a direction away from the conductive pattern, and wherein the first bowing area of the lower electrode is disposed between the conductive pattern and the first lower electrode support.

A semiconductor memory device includes a conductive pattern disposed on a substrate, a lower electrode connected to the conductive pattern, and extending primarily in a first direction, a first lower electrode support spaced apart from the conductive pattern in the first direction and in contact with a sidewall of the lower electrode, a second lower electrode support disposed between the first lower electrode support and the conductive pattern and in contact with the sidewall of the lower electrode, a capacitor dielectric film disposed on the lower electrode, the first lower electrode support and the second lower electrode support and an upper electrode disposed on the capacitor dielectric film, wherein the lower electrode includes at least one bowing area, wherein the bowing area of the lower electrode includes a first point, and a second point closer to the conductive pattern than the first point is, wherein a width in a second direction of the lower electrode at the first point of the lower electrode is smaller than a width in the second direction of the lower electrode at the second point of the lower electrode, and wherein the bowing area of the lower electrode does not overlap either the first lower electrode support or the second lower electrode support in the second direction.

A semiconductor memory device includes a substrate including an active area defined by an element isolation film and extended primarily in a first direction, wherein the active area includes a first portion and a second portion defined on each of both opposing sides of the first portion, a word-line disposed in the substrate and the element isolation film and extending primarily in a second direction different from the first direction, wherein the word-line extends across a portion of the active area disposed between the first portion of the active area and the second portion of the active area, a bit-line contact connected to the first portion of the active area, a bit-line disposed on the bit-line contact and connected to the bit-line contact, wherein the bit-line extends primarily in a third direction different from the first direction and the second direction, a landing pad connected to the second portion of the active area, and a capacitor, wherein the capacitor includes, a lower electrode connected to the landing pad and extending primarily in a fourth direction, a first lower electrode support spaced apart from the landing pad in the fourth direction and in contact with a sidewall of the lower electrode, a second lower electrode support disposed between the first lower electrode support and the landing pad and in contact with the sidewall of the lower electrode, a capacitor dielectric film disposed on the lower electrode, the first lower electrode support and the second lower electrode support, and an upper electrode disposed on the capacitor dielectric film, wherein the lower electrode includes at least one bowing area, wherein a width in the second direction of the lower electrode in the bowing area of the lower electrode increases and then decreases in a direction away from the landing pad, and wherein the bowing area of the lower electrode does not overlap either the first lower electrode support or the second lower electrode support in the second direction.

### BRIEF DESCRIPTION OF DRAWINGS

The above and other aspects and features of the present disclosure will become more apparent by describing in detail illustrative embodiments thereof with reference to the attached drawings, in which:

FIG. 1 is an example diagram illustrating a semiconductor memory device, according to some embodiments.

Each of FIG. 2 and FIG. 3 is an enlarged view of a portion P of FIG. 1.

FIG. 4 and FIG. 5 are diagrams illustrating semiconductor memory devices according to some embodiments, respectively.

FIGS. 6 to 8 are diagrams illustrating semiconductor memory devices according to some embodiments, respectively.

FIG. 9 is a diagram illustrating a semiconductor memory device, according to some embodiments.

FIG. 10 is a diagram illustrating a semiconductor memory device, according to some embodiments.

FIG. 11 is a layout of a semiconductor memory device, according to some embodiments.

FIG. 12 is a layout showing a word-line and a cell active area in FIG. 11.

FIG. 13 is a cross-sectional view cut along A-A in FIG. 11.

FIG. 14 and FIG. 15 are diagrams illustrating a semiconductor memory device, according to some embodiments.

FIG. 16 is a layout diagram illustrating a semiconductor memory device, according to some embodiments.

FIG. 17 is a perspective view illustrating a semiconductor memory device, according to some embodiments.

FIG. 18 is a cross-sectional view cut along lines B-B and C-C of FIG. 16.

FIG. 19 is a layout diagram illustrating a semiconductor memory device, according to some embodiments.

FIG. 20 is a perspective view illustrating a semiconductor memory device, according to some embodiments.

FIG. 21 is a diagram illustrating a semiconductor memory device, according to some embodiments.

FIGS. 22 to 31 are diagrams of intermediate structures corresponding to intermediate step of a semiconductor memory device manufacturing method according to some embodiments.

### DETAILED DESCRIPTIONS

It will be understood that, although the terms “first”, “second”, “third”, and so on may be used herein to illustrate various elements, components, regions, layers and/or sections, these elements, components, regions, layers and/or sections should not necessarily be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

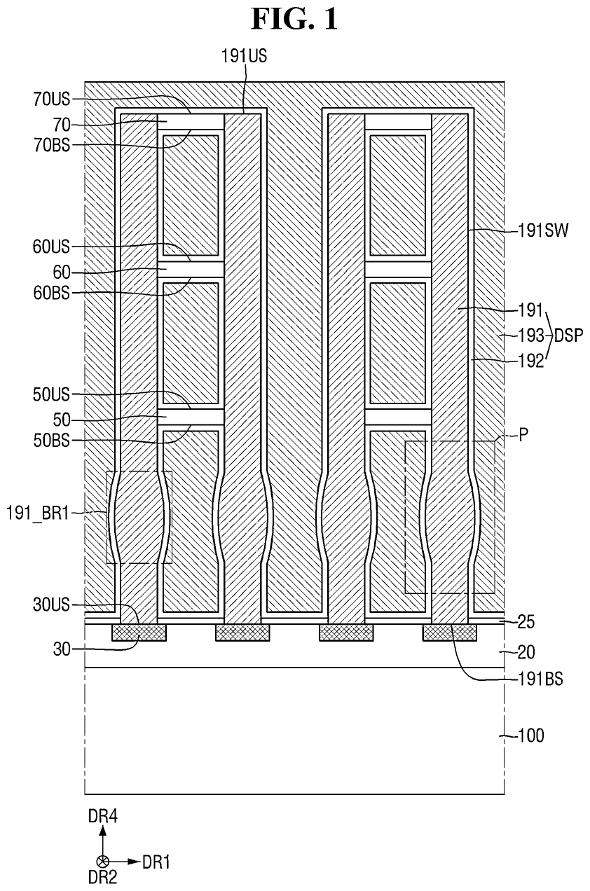

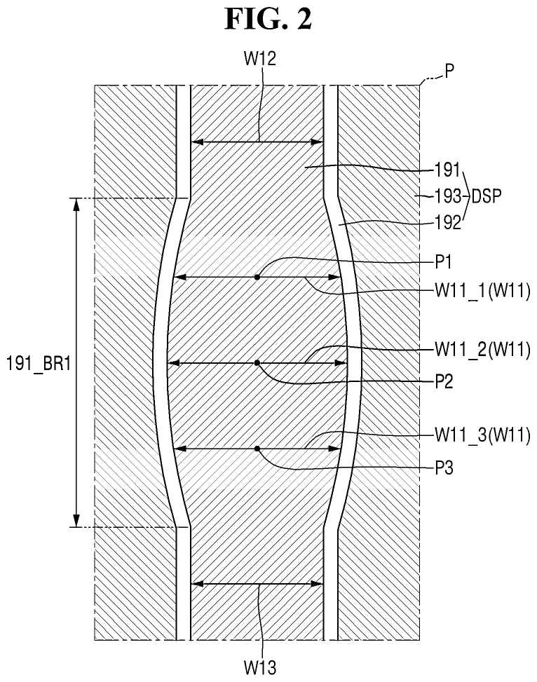

Referring to FIGS. 1 to 3, a semiconductor memory device, according to some embodiments is described.

FIG. 1 is an example diagram illustrating a semiconductor memory device, according to some embodiments. Each of FIG. 2 and FIG. 3 is an enlarged view of a portion P of FIG. 1.

Referring to FIGS. 1 to 3, a semiconductor memory device, according to some embodiments, may include a conductive pattern 30, a lower electrode 191, a capacitor dielectric film 192, an upper electrode 193, and at least one lower electrode support 50, 60 and 70.

The conductive pattern 30 may be disposed on substrate 100. The conductive pattern 30 is shown as being isolated from substrate 100. This is for convenience of illustration, and the present disclosure is not necessarily limited thereto. Unlike what is shown, the conductive pattern 30 may be electrically connected to a conductive area formed on or within the substrate 100.

An interlayer insulating film 20 may be disposed on the substrate 100. The conductive pattern 30 may be disposed within the interlayer insulating film 20.

The substrate 100 may be made of bulk silicon or silicon-on-insulator (SOI). Alternatively, the substrate 100 may be a silicon substrate, or may include a material other than silicon, such as, but not necessarily limited to, silicon germanium, silicon germanium on insulator (SGOI), indium antimonide, lead telluride compound, indium arsenide, indium phosphide, gallium arsenide, or gallium antimonide. In a following description, an example in which the substrate 100 is embodied as a silicon substrate is described.

For example, the interlayer insulating film 20 may include a silicon oxide film, a silicon nitride film, a silicon oxynitride film (SiON), a silicon oxycarbonitride film (SiOCN), a silicon carbonitride film (SiCN), and/or a combination thereof.

The conductive pattern 30 includes conductive material. The conductive pattern 30 may include, for example, a doped semiconductor material, a conductive metal nitride, a conductive metal silicon nitride, a metal carbonitride, a conductive metal silicide, a conductive metal oxide, a two-dimensional material (2D material), and/or a metal. In a semiconductor memory device, according to some embodiments, the two-dimensional material may be a metallic material and/or a semiconductor material. The two-dimensional material may include two-dimensional allotrope or two-dimensional compound. For example, the two-dimensional material may include, but is not necessarily limited to including, graphene, molybdenum disulfide (MoS₂), molybdenum diselenide (MoSe₂), tungsten diselenide (WSe₂), and/or tungsten disulfide (WS₂). For example, the above-described two-dimensional materials are listed by way of example. The two-dimensional material that may be included in the semiconductor device, according to the present disclosure, is not necessarily limited to the above-described materials.

A first etch stop film 25 may be disposed on the interlayer insulating film 20. The first etch stop film 25 might not cover at least a portion of the conductive pattern 30 so as to be exposed.

In one example, the first etch stop film 25 may be disposed on the conductive pattern 30. The first etch stop film 25 may be disposed on an upper surface 30US of the conductive pattern 30. The first etch stop film 25 may include a lower electrode hole exposing at least a portion of the conductive pattern 30.

For example, the first etch stop film 25 may include a silicon nitride film, a silicon carbonitride film, a silicon boronitride film (SiBN), a silicon carbonate film (SiCO), a silicon oxynitride film, and/or a silicon oxycarbonitride film. For example, the silicon carbonate film (SiCO) refers to containing silicon (Si), carbon (C), and oxygen (O), but does not necessarily imply a particular ratio between contents of silicon (Si), carbon (C), and oxygen (O).

A data storage pattern DSP may be disposed on the conductive pattern 30. The data storage pattern DSP may be electrically connected to the conductive pattern 30.

In one example, the data storage patterns DSP may be capacitors. The data storage pattern DSP may include a lower electrode 191, a capacitor dielectric film 192, and an upper electrode 193.

A plurality of lower electrodes 191 may be disposed on the conductive pattern 30. The lower electrode 191 may be connected to the conductive pattern 30. A bottom surface 191BS of the lower electrode 191 is connected to the upper surface 30US of the conductive pattern 30. A portion of the lower electrode 191 may be disposed within the first etch stop film 25.

For example, each lower electrode 191 may have a pillar shape. The lower electrode 191 may extend in an elongate manner primarily in a fourth direction DR4 which is a thickness direction of the substrate 100. A length by which the lower electrode 191 primarily extends in the fourth direction DR4 is greater than a length by which the lower electrode 191 primarily extends in each of directions DR1 and DR2 parallel to the substrate 100. A shape of the lower electrode 191 is described in detail below.

For example, the plurality of lower electrodes 191 may be arranged iteratively along the first direction DR1. The lower electrodes 191 may be arranged iteratively along the second direction DR2. The first direction DR1 and the second direction DR2 may be orthogonal to each other, but is not necessarily limited thereto. The first direction DR1 and the second direction DR2 may be directions parallel to the substrate 100, and may be perpendicular to the fourth direction DR4.

The lower electrode 191 may include, for example, a conductive metal nitride such as titanium nitride, tantalum nitride, niobium nitride or tungsten nitride, a metal such as ruthenium, iridium, titanium or tantalum, and a conductive metal oxide such as iridium oxide or niobium oxide, etc. However, the present disclosure is not necessarily limited thereto. In the semiconductor memory device, according to some embodiments, the lower electrode 191 may include titanium nitride (TiN). Moreover, in the semiconductor memory device, according to some embodiments, the lower electrode 191 may include niobium nitride (NbN).

The at least one lower electrode support 50, 60 and 70 may be disposed on the first etch stop film 25. Each of the at least one lower electrode support 50, 60 and 70 may support the lower electrode 191.

For example, a plurality of lower electrode supports 50, 60, and 70 may be disposed on the first etch stop layer 25. The plurality of lower electrode supports 50, 60, and 70 may include a first lower electrode support 50, a second lower electrode support 60, and a third lower electrode support 70 sequentially arranged in the fourth direction DR4 on the first etch stop film 25.

The first lower electrode support 50, the second lower electrode support 60, and the third lower electrode support 70 may be spaced apart from the first etch stop layer 25 in the fourth direction DR4. The first lower electrode support 50, the second lower electrode support 60, and the third lower electrode support 70 may be spaced apart from each other in the fourth direction DR4.

For example, the first lower electrode support 50 may be the lowest lower electrode support among the lower electrode supports 50, 60, and 70. The first lower electrode support 50 may be the lower electrode support closest to the conductive pattern 30 in the fourth direction DR4. Between the first lower electrode support 50 and the conductive pattern 30, no additional lower electrode support is disposed.

The third lower electrode support 70 may be the topmost lower electrode support among lower electrode supports 50, 60, and 70. The third lower electrode support 70 may be the lower electrode support furthest from the conductive pattern 30 in the fourth direction DR4.

Each of the first lower electrode support 50, the second lower electrode support 60, and the third lower electrode support 70 may be in contact with the lower electrode 191. Each of the first lower electrode support 50, the second lower electrode support 60, and the third lower electrode support 70 may be in contact with a portion of a sidewall 191SW of the lower electrode.

Although it is shown that the number of the lower electrode supports in contact with the sidewall 191SW of the lower electrode is three, the technical idea of the present disclosure is not necessarily limited thereto. Unlike what is shown, in one example, two or more lower electrode supports may be disposed between the first lower electrode support 50 and the third lower electrode support 70. In an example, between the first lower electrode support 50 and the third lower electrode support 70, no lower electrode support may be disposed.

The first lower electrode support 50 may include an upper surface 50US and a bottom surface 50BS opposite to each other in the fourth direction DR4. The second lower electrode support 60 may include an upper surface 60US and a bottom surface 60BS opposite to each other in the fourth direction DR4. The third lower electrode support 70 may include an upper surface 70US and a bottom surface 70BS opposite to each other in the fourth direction DR4. Each of the bottom surface 50BS of the first lower electrode support, the bottom surface 60BS of the second lower electrode support, and the bottom surface 70BS of the third lower electrode support may face the conductive pattern 30.

Each of the lower electrodes 191 might not protrude in the fourth direction DR4 beyond the third lower electrode support 70. The lower electrode 191 might not protrude in the fourth direction DR4 beyond the upper surface 70US of the third lower electrode support.

For example, the third lower electrode support 70 might not be disposed on the upper surface 191US of the lower electrode. The third lower electrode support 70 might not cover the upper surface 191US of the lower electrode.

Each of the first lower electrode support 50, the second lower electrode support 60 and the third lower electrode support 70 may include, for example, silicon nitride, silicon carbonitride, silicon boronitride, silicon carbonate, silicon oxynitride and/or silicon oxycarbonitride. In FIG. 1, it is shown that a thickness in the fourth direction DR4 of the third lower electrode support 70 is equal to each of a thickness in the fourth direction DR4 of the first lower electrode support 50 and a thickness in the fourth direction DR4 of the second lower electrode support 60. However, the present disclosure is not necessarily limited thereto. Unlike what is shown, the thickness in the fourth direction DR4 of the third lower electrode support 70 may be different from the thickness in the fourth direction DR4 of the first lower electrode support 50 and/or the thickness in the fourth direction DR4 of the second lower electrode support 60.

The lower electrode 191 may include at least one bowing area. For example, the lower electrode 191 may include at least one first bowing area 191_BR1. The at least one first bowing area 191_BR1 is disposed between the third lower electrode support 70 and the conductive pattern 30.

The first bowing area 191_BR1 of the lower electrode might not overlap with the first lower electrode support 50, the second lower electrode support 60, and the third lower electrode support 70 in the first direction DR1. The first bowing area 191_BR1 of the lower electrode might not overlap with the first lower electrode support 50, the second lower electrode support 60, and the third lower electrode support 70 in the second direction DR2.

In the semiconductor memory device, according to some embodiments, the lower electrode 191 may include one first bowing area 191_BR1. For example, the first bowing area 191_BR1 of the lower electrode may be disposed between the first lower electrode support 50 as the lowest lower electrode support and the conductive pattern 30.

The first bowing area 191_BR1 of the lower electrode may be disposed between the bottom surface 50BS of the first lower electrode support and the upper surface 30US of the conductive pattern. The first bowing area 191_BR1 of the lower electrode might not overlap with the first lower electrode support 50 in the first direction DR1. For example, a portion having the largest width in the first bowing area 191_BR1 of the lower electrode might not overlap with the first lower electrode support 50 in the first direction DR1.

In the first bowing area 191_BR1 of the lower electrode, the sidewall 191SW of the lower electrode may have a convex shape. In the first bowing area 191_BR1 of the lower electrode, a width W11 in the first direction DR1 of the lower electrode 191 may increase and then decrease in a direction away from the conductive pattern 30. In the first bowing area 191_BR1 of the lower electrode, the width W11 in the first direction DR1 of the lower electrode 191 may increase and then decrease in a direction away from the first lower electrode support 50.

In the first bowing area 191_BR1 of the lower electrode, a width in the second direction DR2 of the lower electrode 191 may increase and then decrease in a direction away from the conductive pattern 30.

For example, the first bowing area 191_BR1 of the lower electrode may include a first point P1, a second point P2, and a third point P3. The second point P2 of the first bowing area 191_BR1 is closer to the conductive pattern 30 than the first point P1 of the first bowing area 191_BR1 is. The third point P3 of the first bowing area 191_BR1 is closer to the conductive pattern 30 than the second point P2 of the first bowing area 191_BR1 is. The second point P2 of the first bowing area 191_BR1 is located between the first point P1 of the first bowing area 191_BR1 and the third point P3 of the first bowing area 191_BR1.

A width W11_2 in the first direction DR1 of the lower electrode 191 at the second point P2 of the first bowing area 191_BR1 may be greater than a width W11_1 in the first direction DR1 of the lower electrode 191 at the first point P1 of the first bowing area 191_BR1. The width W11 2 in the first direction DR1 of the lower electrode 191 at the second point P2 of the first bowing area 191_BR1 may be greater than a width W11_3 in the first direction DR1 of the lower electrode 191 at the third point P3 of the first bowing area 191_BR1.

In FIG. 1 and FIG. 2, in an area between the first bowing area 191_BR1 of the lower electrode and the first lower electrode support 50, a width W12 in the first direction DR1 of the lower electrode 191 may be constant in a direction away from the conductive pattern 30. In an area between the first bowing area 191_BR1 of the lower electrode and the conductive pattern 30, a width W13 in the first direction DR1 of the lower electrode 191 may be constant in a direction away from the conductive pattern 30.

In FIG. 1 and FIG. 3, in an area between the first bowing area 191_BR1 of the lower electrode and the first lower electrode support 50, the width W12 in the first direction DR1 of the lower electrode 191 may increase in a direction away from the conductive pattern 30. In an area between the first bowing area 191_BR1 of the lower electrode and the conductive pattern 30, the width W13 in the first direction DR1 of the lower electrode 191 may increase in a direction away from the conductive pattern 30.

Unlike what is shown, in one example, in an area between the first bowing area 191_BR1 of the lower electrode and the first lower electrode support 50, the width W12 in the first direction DR1 of the lower electrode 191 may be constant in a direction away from the conductive pattern 30. In an area between the first bowing area 191_BR1 of the lower electrode and the conductive pattern 30, the width W13 in the first direction DR1 of the lower electrode 191 may increase in a direction away from the conductive pattern 30.

Unlike what is shown, in an example, in an area between the first bowing area 191_BR1 of the lower electrode and the first lower electrode support 50, the width W12 in the first direction DR1 of the lower electrode 191 may increase in a direction away from the conductive pattern 30. In an area between the first bowing area 191_BR1 of the lower electrode and the conductive pattern 30, the width W13 in the first direction DR1 of the lower electrode 191 may be constant in a direction away from the conductive pattern 30.

The capacitor dielectric film 192 may be disposed on the lower electrode 191. The capacitor dielectric film 192 may be disposed on the lower electrode support 50, 60, and 70.

The capacitor dielectric film 192 may extend along the sidewall 191SW of the lower electrode, the upper surface 70US of the third lower electrode support, and the bottom surface 70BS of the third lower electrode support. The capacitor dielectric film 192 may extend along the upper surface 50US of the first lower electrode support, the bottom surface 50BS of the first lower electrode support, the upper surface 60US of the second lower electrode support, and the bottom surface 60BS of the second lower electrode support.

For example, the capacitor dielectric film 192 may include silicon oxide, silicon nitride, silicon oxynitride, hafnium oxide, hafnium silicon oxide, hafnium zirconium oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, lead zirconium titanium oxide, yttrium oxide, aluminum oxide, lead scandium tantalum oxide, lead zinc niobate, and/or combinations thereof. However, the present disclosure is not necessarily limited thereto.

In one example, the capacitor dielectric film 192 may include a stacked film structure in which a zirconium oxide film, an aluminum oxide film, and a zirconium oxide film are sequentially stacked. In an example, the capacitor dielectric film 192 may include a dielectric film including hafnium (Hf). The description of the capacitor dielectric film 192 as set forth above is an example, and the technical idea of the present disclosure is not necessarily limited thereto.

The capacitor dielectric film 192 may include a ferroelectric material, an antiferroelectric material, and/or a paraelectric material. For example, the capacitor dielectric film 192 may include a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, or a combination of a ferroelectric material, an antiferroelectric material, and/or a paragenetic material.

Unlike what is described above, the data storage pattern DSP may be embodied as a variable resistance pattern that may be switched to between two resistance states under an electrical pulse applied to the memory element. For example, the data storage pattern DSP may include a phase-change material whose crystal state changes depending on an amount of current, perovskite compounds, a transition metal oxide, a magnetic material, a ferromagnetic material, or an antiferromagnetic material.

The upper electrode 193 may be disposed on the capacitor dielectric film 192. The upper electrode 193 may fill a space between adjacent lower electrodes 191. The upper electrode 193 may fill spaces between two of the lower electrode supports 50, 60 and 70 adjacent to each other in the fourth direction DR4. The upper electrode 193 may fill a space between the first lower electrode support 50 and the interlayer insulating film 20.

The upper electrode 193 may include, for example, a doped semiconductor material, a conductive metal nitride such as titanium nitride, tantalum nitride, niobium nitride or tungsten nitride, etc., a metal such as ruthenium, iridium, titanium or tantalum, etc. and a conductive metal oxide such as iridium oxide or niobium oxide, etc. However, the present disclosure is not necessarily limited thereto.

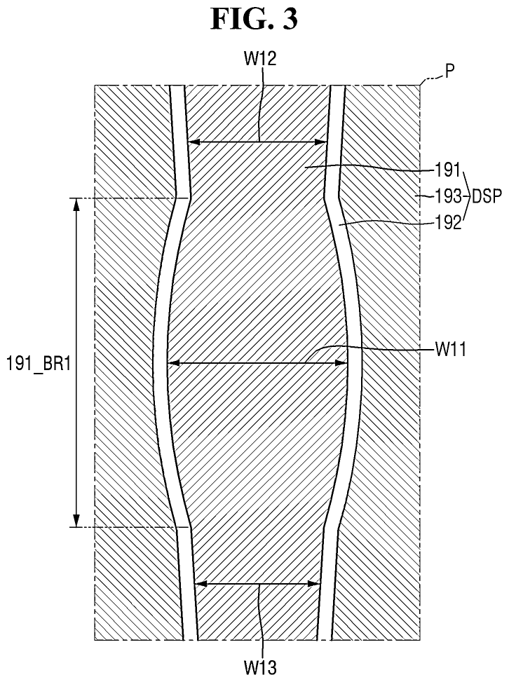

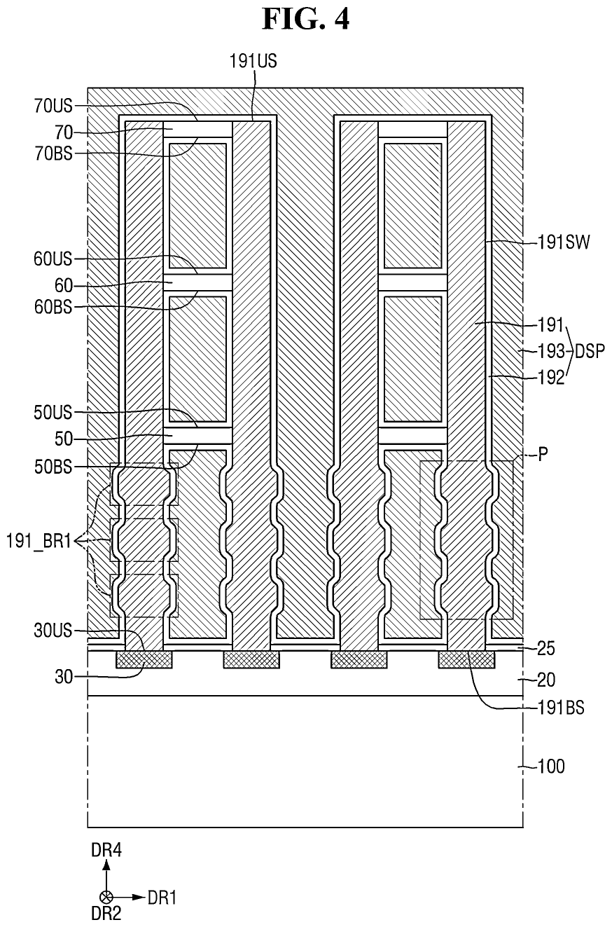

FIG. 4 and FIG. 5 are diagrams illustrating semiconductor memory devices according to some embodiments, respectively. For convenience of description, following description focuses on differences thereof from the descriptions set forth above using FIG. 1 to FIG. 3. For reference, FIG. 5 is an enlarged view of a portion P in FIG. 4.

Referring to FIG. 4 and FIG. 5, in the semiconductor memory device, according to some embodiments, each lower electrode 191 may include a plurality of first bowing areas 191_BR1 of the lower electrode disposed between the third lower electrode support 70 and the conductive pattern 30.

For example, the plurality of first bowing areas 191_BR1 of the lower electrode may be disposed between the first lower electrode support 50 as the lowest lower electrode support and the conductive pattern 30. The plurality of first bowing areas 191_BR1 of the lower electrode may be disposed between the bottom surface 50BS of the first lower electrode support and the upper surface 30US of the conductive pattern.

For example, the plurality of first bowing areas 191_BR1 of the lower electrode may include a first sub-bowing area 191_BR11, a second sub-bowing area 191_BR12, and a third sub-bowing area 191_BR13.

The second sub-bowing area 191_BR12 may be disposed between the first sub-bowing area 191_BR11 and the third sub-bowing area 191_BR13. The second sub-bowing area 191_BR12 may be spaced apart from the first sub-bowing area 191_BR11 in the fourth direction DR4. The second sub-bowing area 191_BR12 may be spaced apart from the third sub-bowing area 191_BR13 in the fourth direction DR4.

Each of the first sub-bowing area 191_BR11, the second sub-bowing area 191_BR12, and the third sub-bowing area 191_BR13 may be disposed between the bottom surface 50BS of the first lower electrode support and the upper surface 30US of the conductive pattern. Each of the first sub-bowing area 191_BR11, the second sub-bowing area 191_BR12, and the third sub-bowing area 191_BR13 might not overlap with the first lower electrode support 50 in the first direction DR1.

In the first sub-bowing area 191_BR11, the second sub-bowing area 191_BR12, and the third sub-bowing area 191_BR13, the sidewall 191SW of the lower electrode may have a convex shape. In the first sub-bowing area 191_BR11, the width in the first direction DR1 of the lower electrode 191 may increase and then decrease in a direction away from the conductive pattern 30. In the second sub-bowing area 191_BR12, the width in the first direction DR1 of the lower electrode 191 may increase and then decrease in a direction away from the conductive pattern 30. In the third sub-bowing area 191_BR13, the width in the first direction DR1 of the lower electrode 191 may increase and then decrease in a direction away from the conductive pattern 30.

The first bowing area 191_BR1 of the lower electrode is shown as including the three sub-bowing areas 191_BR11, 191_BR12, and 191_BR13. However, the present disclosure is not necessarily limited thereto. Unlike what is shown, the first bowing area 191_BR1 of the lower electrode may include two or four or more sub-bowing areas.

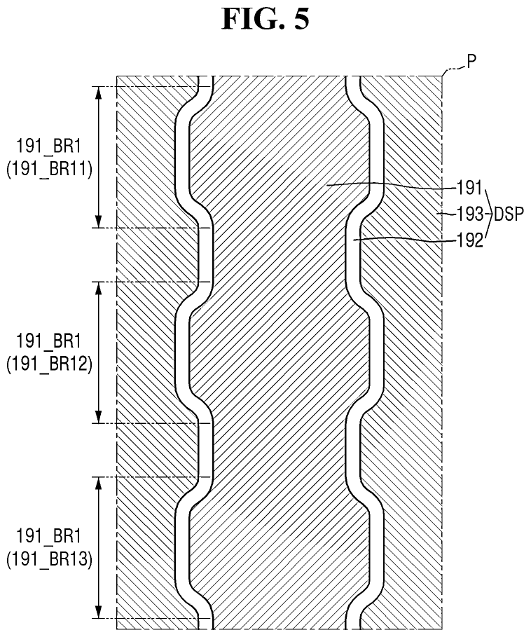

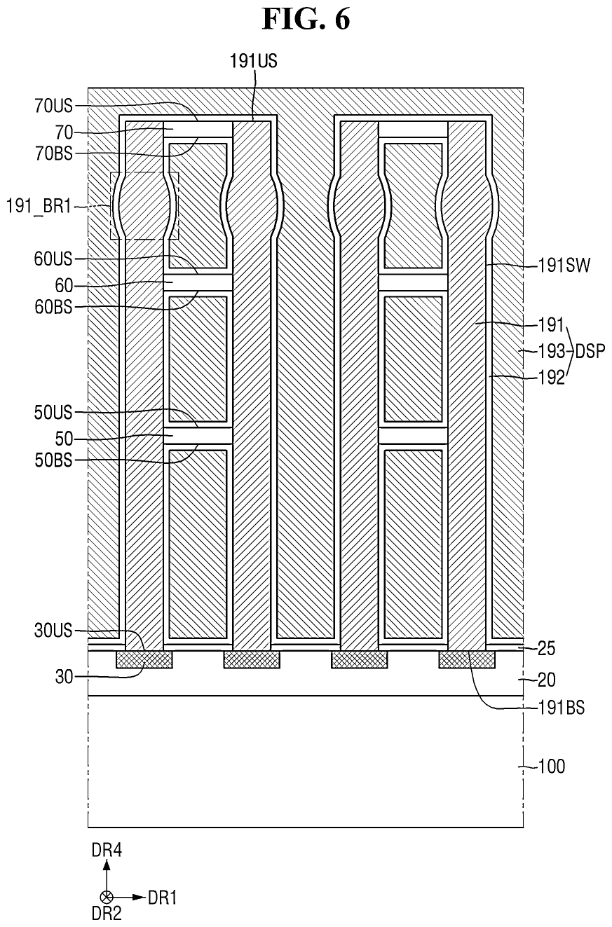

FIGS. 6 to 8 are diagrams illustrating semiconductor memory devices according to some embodiments, respectively. For convenience of description, following descriptions are based on differences thereof from the descriptions as set forth above using FIG. 1 to FIG. 5. To the extent that an element is not described in detail with respect to these figures, it may be understood that the element is at least similar to a corresponding element that has been described elsewhere within the present disclosure.

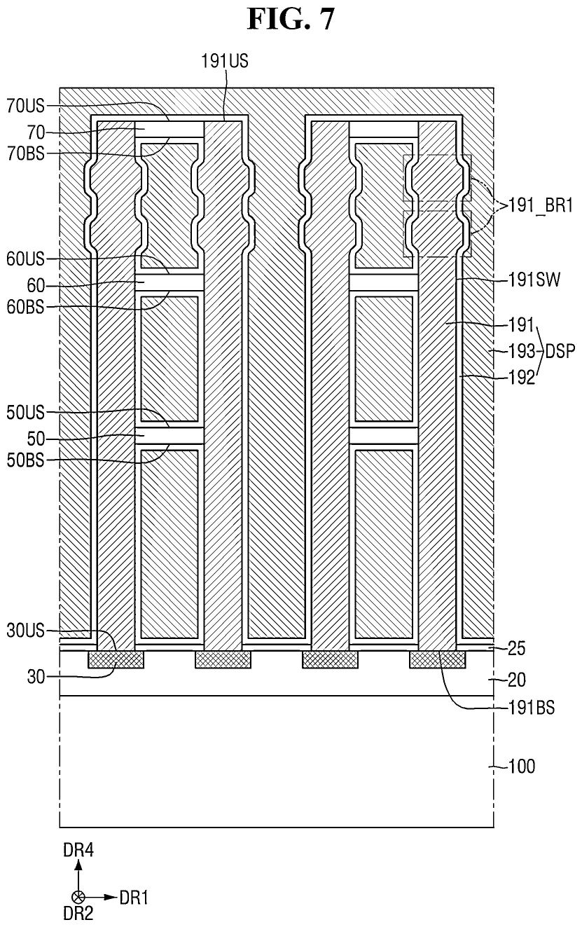

Referring to FIG. 6 and FIG. 7, in the semiconductor memory device, according to some embodiments, at least one first bowing area 191_BR1 of the lower electrode may be disposed between the second lower electrode support 60 and the third lower electrode support 70.

The at least one first bowing area 191_BR1 of the lower electrode may be disposed between the second lower electrode support 60 and the third lower electrode support 70 as the topmost lower electrode support. The lower electrode 191 might not include a portion that protrudes in the fourth direction DR4 beyond the upper surface 70US of the third lower electrode support.

The at least one first bowing area 191_BR1 of the lower electrode might not overlap with the second lower electrode support 60 and the third lower electrode support 70 in the first direction DR1. The at least one first bowing area 191_BR1 of the lower electrode may be disposed between the bottom surface 70BS of the third lower electrode support and the upper surface 60US of the second lower electrode support.

In FIG. 6, the lower electrode 191 may include one first bowing area 191_BR1 disposed between the upper surface 60US of the second lower electrode support and the bottom surface 70BS of the third lower electrode support.

In FIG. 7, the lower electrode 191 may include a plurality of first bowing areas 191_BR1 disposed between the upper surface 60US of the second lower electrode support and the bottom surface 70BS of the third lower electrode support. The first bowing areas 191_BR1 may be spaced apart from each other in the fourth direction DR4. Each of the first bowing areas 191_BR1 might not overlap with the second lower electrode support 60 and the third lower electrode support 70 in the first direction DR1.

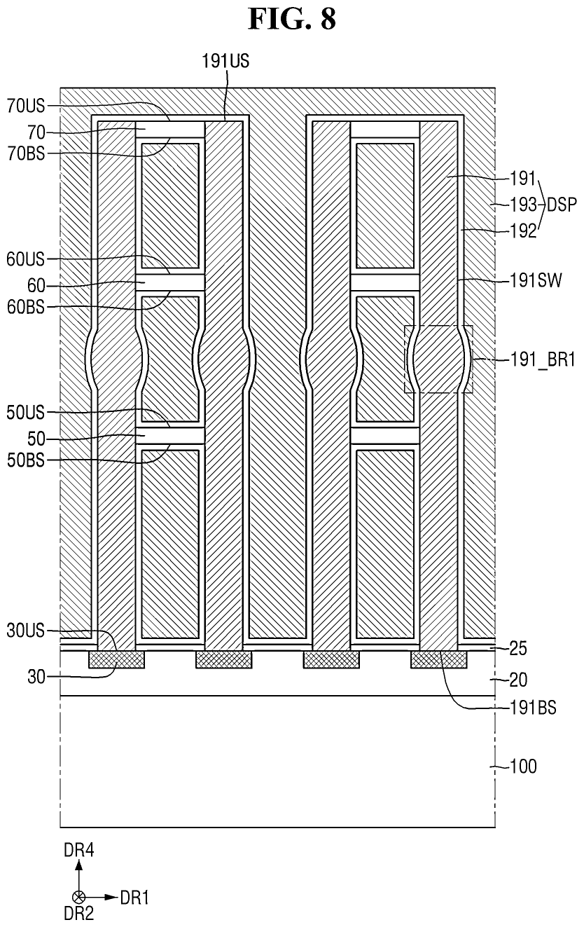

Referring to FIG. 8, in the semiconductor memory device, according to some embodiments, the at least one first bowing area 191_BR1 of the lower electrode may be disposed between the first lower electrode support 50 and the second lower electrode support 60.

The at least one first bowing area 191_BR1 of the lower electrode may be disposed between the second lower electrode support 60 and the first lower electrode support 50 as the lowest lower electrode support. A portion of the lower electrode 191 may protrude in the fourth direction DR4 beyond the upper surface 60US of the second lower electrode support disposed above the first bowing area 191_BR1 of the lower electrode.

The at least one first bowing area 191_BR1 of the lower electrode might not overlap with the first lower electrode support 50 and the second lower electrode support 60 in the first direction DR1. The at least one first bowing area 191_BR1 of the lower electrode may be disposed between the bottom surface 60BS of the second lower electrode support and the upper surface 50US of the first lower electrode support.

Although one first bowing area 191_BR1 is shown as being disposed between the first lower electrode support 50 and the second lower electrode support 60, the present disclosure is not necessarily limited thereto. Unlike what is shown, as shown in FIG. 4 and FIG. 7, the plurality of the first bowing areas 191_BR1 may be disposed between the upper surface 50US of the first lower electrode support and the bottom surface 60BS of the second lower electrode support.

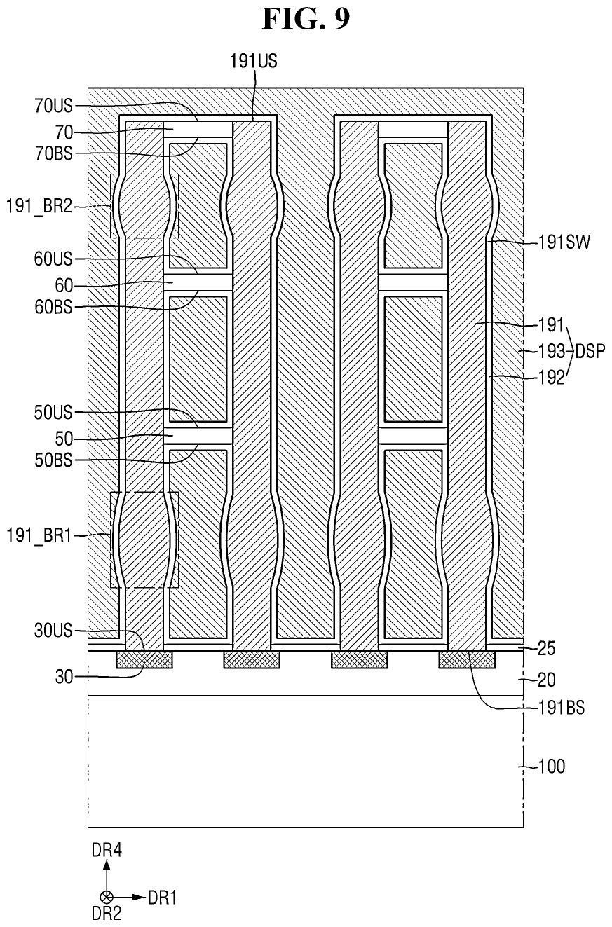

FIG. 9 is a diagram illustrating a semiconductor memory device, according to some embodiments. FIG. 10 is a diagram illustrating a semiconductor memory device, according to some embodiments. For convenience of description, following descriptions focus on differences thereof from the descriptions as set forth above using FIG. 1 to FIG. 5. To the extent that an element is not described in detail with respect to these figures, it may be understood that the element is at least similar to a corresponding element that has been described elsewhere within the present disclosure.

Referring to FIG. 9, in the semiconductor memory device, according to some embodiments, the lower electrode 191 may further include at least one second bowing area 191_BR2.

The second bowing area 191_BR2 of the lower electrode may be disposed between the second lower electrode support 60 and the third lower electrode support 70. The second bowing area 191_BR2 of the lower electrode may be disposed between the upper surface 60US of the second lower electrode support and the bottom surface 70BS of the third lower electrode support.

The second bowing area 191_BR2 of the lower electrode might not overlap with the second lower electrode support 60 and the third lower electrode support 70 in the first direction DR1. A width in the first direction DR1 of the lower electrode 191 in the second bowing area 191_BR2 of the lower electrode may increase and then decrease in a direction away from the bottom surface 70BS of the third lower electrode support.

Unlike what is shown, the second bowing area 191_BR2 of the lower electrode may be disposed between the first lower electrode support 50 and the second lower electrode support 60. Moreover, unlike what is shown, the lower electrode 191 may include a plurality of second bowing areas 191_BR2 disposed between the second lower electrode support 60 and the third lower electrode support 70.

The description about the second bowing area 191_BR2 of the lower electrode may be substantially the same as the description about the first bowing area 191_BR1 of the lower electrode as described with reference to FIGS. 1 to 5. To the extent that an element is not described in detail with respect to these figures, it may be understood that the element is at least similar to a corresponding element that has been described elsewhere within the present disclosure.

Referring to FIG. 10, in the semiconductor memory device, according to some embodiments, the third lower electrode support 70 may cover the upper surface 191US of the lower electrode.

The third lower electrode support 70 may be disposed on the upper surface 191US of the lower electrode. A portion of the third lower electrode support 70 may protrude in the fourth direction DR4 beyond the upper surface 191US of the lower electrode.

For example, the third lower electrode support 70 may contact the upper surface 191US of the lower electrode. The bottom surface 70BS of the third lower electrode support may include an unevenness. Since the upper surface 191US of the lower electrode is in contact with the third lower electrode support 70, the capacitor dielectric film 192 is not disposed between the upper surface 191US of the lower electrode and the bottom surface 70BS of the third lower electrode support.

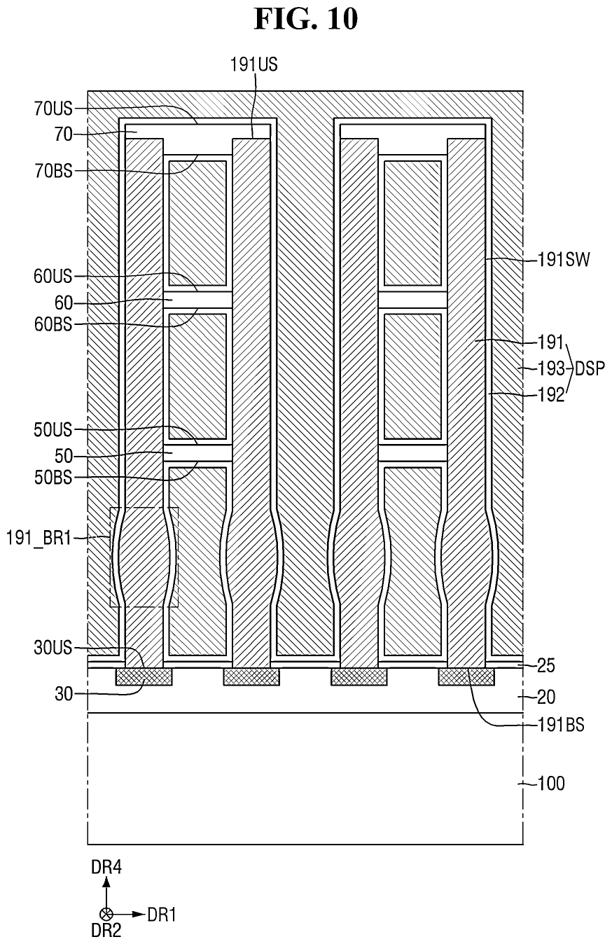

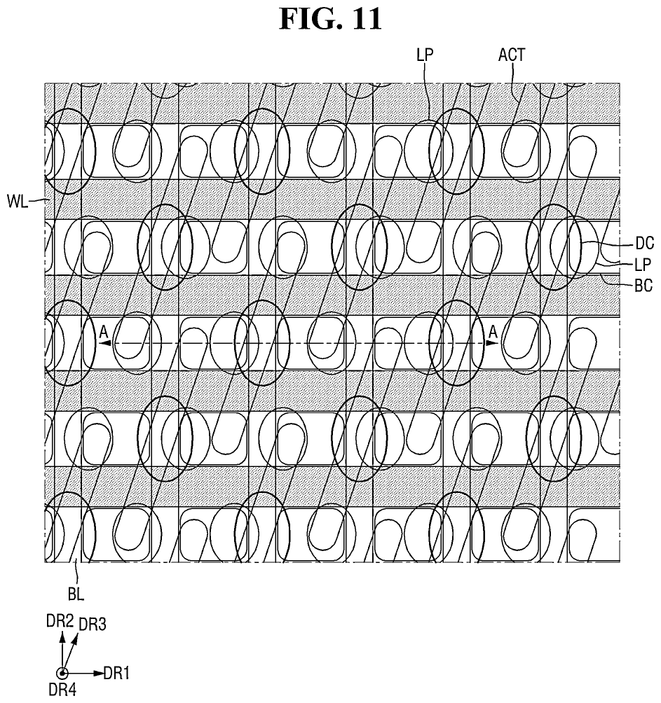

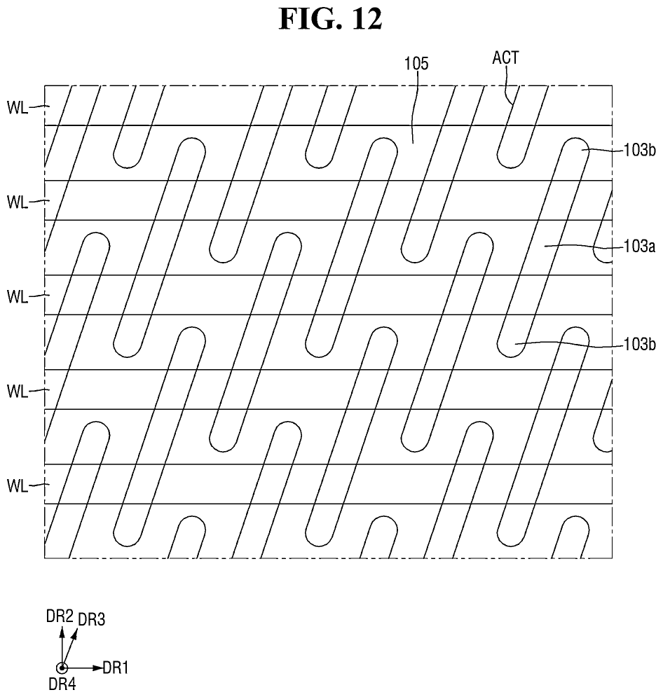

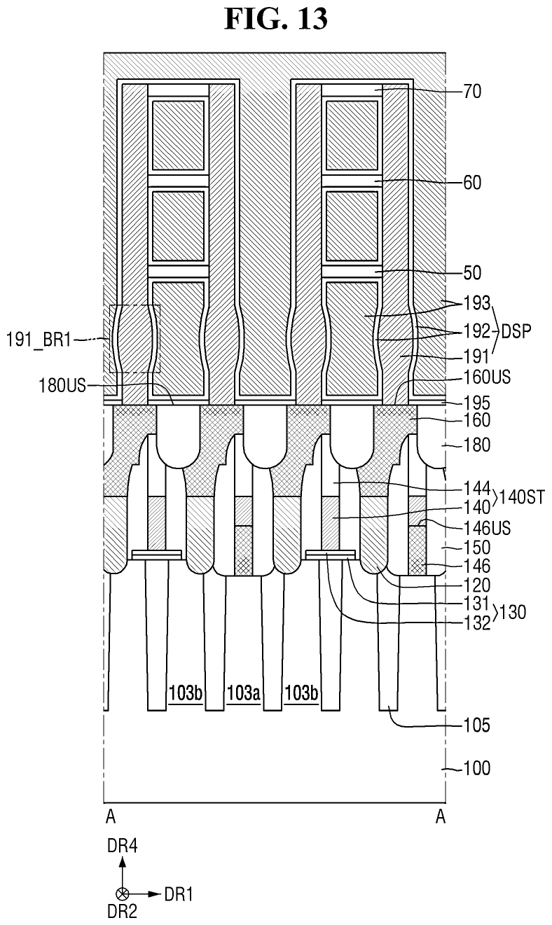

FIG. 11 is a layout of a semiconductor memory device, according to some embodiments. FIG. 12 is a layout showing a word-line and a cell active area in FIG. 11. FIG. 13 is a cross-sectional view cut along A-A in FIG. 11.

For reference, FIG. 11 shows an example layout of Dynamic Random Access Memory (DRAM) excluding the data storage pattern DSP. However, the present disclosure is not necessarily limited thereto.

Moreover, the first direction DR1 in FIG. 11 may correspond to the first direction DR1 in FIG. 1. The second direction DR2 in FIG. 11 may correspond to the second direction DR2 in FIG. 1. However, the present disclosure is not necessarily limited thereto. Unlike what is described above, the first direction DR1 in FIG. 11 may correspond to the second direction DR2 in FIG. 1, and the second direction DR2 in FIG. 11 may correspond to the first direction DR1 in FIG. 1.

Referring to FIG. 11 and FIG. 12, the semiconductor memory device, according to some embodiments, may include a plurality of cell active areas ACT.

The cell active area ACT may be defined by a cell element isolation film 105 formed within the substrate (100 of FIG. 13). According to a reduction of the design rule (for example, a reduction in feature sizes of the design rule) of the semiconductor memory device, the cell active area ACT may extend in a form of a bar extending primarily in a diagonal line or an oblique line, as shown. For example, the cell active area ACT may extend in the third direction DR3.

As used herein, the phrase “extending primarily” may mean that while the element may be seen as extending in all spatial directions, the longest direction of extension is seen as the primary direction and so an element that extends primarily in one direction has its longest extension in that direction.

A plurality of gate electrodes extending primarily in the first direction DR1 may be disposed across the cell active area ACT. The plurality of gate electrodes may extend parallel to each other. For example, the plurality of gate electrodes may be a plurality of word-lines WL. The word-lines WL may be spaced from each other by an equal spacing. A width of each of the word-lines WL or the spacing between the word-lines WL may be determined according to the design rule.

The two word-lines WL extending primarily in the first direction DR1 may divide each cell active area ACT into three portions. The cell active area ACT may include a storage connection area 103b and a bit-line connection area 103a. The bit-line connection area 103a may be located at a middle portion of the cell active area ACT, while the storage connection area 103b may be located at each of both opposing ends of the cell active area ACT.

For example, the bit-line connection area 103a may be an area connected to a bit-line BL, and the storage connection area 103b may be an area connected to the data storage pattern (DSP in FIG. 13). For example, the bit-line connection area 103a may correspond to a common drain area, and the storage connection area 103b may correspond to a source area. Each word-line WL and the bit-line connection area 103a and the storage connection area 103b adjacent thereto may constitute a transistor.

On the word-line WL, a plurality of bit-lines BL extending primarily in the second direction DR2 orthogonal to the word-line WL may be disposed. The plurality of bit-lines BL may extend parallel to each other. The bit-lines BL may be spaced from each other by an equal spacing. A width of the bit-line BL or the spacing between the bit-lines BL may be determined according to the design rule.

The fourth direction DR4 may be perpendicular to the first direction DR1, the second direction DR2, and the third direction DR3.

The semiconductor memory device, according to some embodiments, may include various contact arrangements formed on the cell active area ACT. The various contact arrangements may include, for example, a direct contact DC, a buried contact BC, and a landing pad LP.

In this regard, the direct contact DC may mean a contact that electrically connects the cell active area ACT to the bit-line BL to each other. The buried contact BC may mean a contact that connects the cell active area ACT to the lower electrode (191 in FIG. 13) of the data storage pattern (DSP in FIG. 13).

Due to the arrangement structure, a contact area between the buried contact BC and the cell active area ACT may be relatively small. Accordingly, the conductive landing pad LP may be introduced to increase the contact area thereof with the cell active area ACT and a contact area thereof with the lower electrode (191 in FIG. 13) of the data storage pattern.

In the semiconductor memory device, according to some embodiments, the landing pad LP may be disposed between the buried contact BC and the lower electrode (191 of FIG. 13) of the data storage pattern. The contact area may be increased via the introduction of the landing pad LP, such that contact resistance between the cell active area ACT and the lower electrode (191 in FIG. 13) of the data storage pattern may be reduced.

For example, the conductive pattern 30 in FIG. 1, FIG. 4, and FIG. 6 to FIG. 10 may correspond to the landing pad LP.

In the semiconductor memory device, according to some embodiments, the direct contact DC may be disposed on a central portion of the cell active area ACT. The buried contact BC may be disposed on each of both opposing ends of the cell active area ACT. The direct contact DC may be connected to the bit-line connection area 103a. The buried contact BC may be connected to the storage connection area 103b.

As the buried contact BC is disposed on each of both opposing ends of the cell active area ACT, the landing pad LP may be disposed adjacent to each of both opposing ends of the cell active area ACT and may overlap a portion of the buried contact BC. For example, the buried contact BC may overlap the cell active area ACT and the element isolation film (105 in FIG. 13) between adjacent word-lines WL and between adjacent bit-lines BL.

The word-line WL may be buried within the substrate 100. The word-line WL may extend across a portion of the active area ACT between the direct contact DC and the buried contact BC.

As shown, two word-lines WL may extend across one active area ACT. As the active area ACT extends primarily in a diagonal shape, the word-line WL may have an angle less than 90 degree with respect to the active area ACT.

The direct contacts DC may be arranged symmetrically. The buried contacts BC may be arranged symmetrically. Thus, the direct contacts DC may be arranged in a straight line along each of the first direction DR1 and the second direction DR2. The buried contacts BC may be arranged in a straight line along each of the first direction DR1 and the second direction DR2.

In one example, unlike the direct contact DC and the buried contact BC, the landing pads LP may be arranged in a zigzag form in the second direction DR2 where the bit-line BL extends primarily along. Further, the landing pads LP may be arranged in the first direction D1 in which the word-line WL extends primarily along so as to overlap the same side portions of corresponding bit-lines BL, respectively.

For example, the landing pads LP arranged in a first line in the first direction may overlap left side portions of corresponding bit-lines BL, respectively. The landing pads LP arranged in a second line in the first direction may overlap right side portions of corresponding bit-lines BL, respectively.

Referring to FIGS. 11 to 13, the semiconductor memory device, according to some embodiments, may include a plurality of bit-line structures 140ST, a plurality of storage contacts 120, a plurality of bit-line contacts 146, and the date storage pattern DSP.

The cell element isolation film 105 may be disposed within the substrate 100. The cell element isolation film 105 may have an STI (shallow trench isolation) structure with excellent element isolation ability. The cell element isolation film 105 may define the cell active area ACT in the memory cell area.

The cell active area ACT defined by the cell element isolation film 105 may have an elongate island shape including a minor axis and a major axis as shown in FIG. 11 and FIG. 12. The cell active area ACT may have an oblique shape to have an angle smaller than 90 degrees with respect to the word-line WL formed in the element isolation film 105. Further, the cell active area ACT may have an oblique shape to have an angle smaller than 90 degrees with respect to the bit-line BL formed on the element isolation film 105.

The cell element isolation film 105 may include, for example, a silicon oxide film, a silicon nitride film, and/or a silicon oxynitride film. However, the present disclosure is not necessarily limited thereto.

The element isolation film 105 is shown to be formed as one insulating film. However, this is for convenience of illustration. The present disclosure is not necessarily limited thereto. Depending on a spacing between adjacent cell active areas ACT, the cell element isolation film 105 may be formed as one insulating film, or may be formed as a plurality of insulating films.

In FIG. 13, an upper surface of the cell element isolation film 105 and the upper surface of the substrate 100 are shown as being coplanar with each other. However, this is for convenience of illustration. The present disclosure is not necessarily limited thereto.

The bit-line structure 140ST may include a cell conductive line 140, a cell line capping film 144, and a bit-line spacer 150.

The cell conductive line 140 may be disposed on the substrate 100 and the cell element isolation film 105 in which the word-line WL is formed. The cell conductive line 140 may intersect with the cell element isolation film 105 and the cell active area ACT defined by the cell element isolation film 105. The cell conductive line 140 may intersect the word-line WL. In this regard, the cell conductive line 140 may correspond to the bit-line BL. For example, the cell conductive line 140 may be the bit-line BL in FIG. 11.

For example, the cell conductive line 140 may include a semiconductor material doped with impurities, a conductive silicide compound, a conductive metal nitride, a two-dimensional (2D material), and/or a metal.

The cell conductive line 140 is shown to be embodied as a single film. This is for convenience of illustration and the present disclosure is not necessarily limited thereto. For example, unlike what is shown, the cell conductive line 140 may include a stack of a plurality of conductive films.

The cell line capping film 144 may be disposed on the cell conductive line 140. The cell line capping film 144 may extend along an upper surface of the cell conductive line 140 and in the second direction DR2. For example, the cell line capping film 144 may include a silicon nitride film, silicon oxynitride, silicon carbonitride, and/or silicon oxycarbonitride.

In the semiconductor memory device, according to some embodiments, the cell line capping film 144 may include a silicon nitride film. Although the cell line capping film 144 is shown to be embodied as a single film, the present disclosure is not necessarily limited thereto.

The bit-line spacer 150 may be disposed on a sidewall of each of the cell conductive line 140 and the cell line capping film 144. The bit-line spacer 150 extends in an elongate manner primarily in the second direction DR2.

The bit-line spacer 150 is shown to be embodied as a single film. This is for convenience of illustration and the present disclosure is not necessarily limited thereto. For example, in an example, unlike what is shown, the bit-line spacer 150 may have a multilayer structure. The bit-line spacer 150 may include, for example, a silicon oxide film, a silicon nitride film, a silicon oxynitride film (SiON), a silicon oxycarbonitride film (SiOCN), air, and/or a combination thereof. However, the present disclosure is not necessarily limited thereto.

A cell insulating film 130 may be disposed on the substrate 100 and the cell element isolation film 105. For example, the cell insulating film 130 may be disposed on an upper surface of the substrate 100 and the cell element isolation film 105 in an area in which the bit-line contact 146 and the storage contact 120 are not formed. The cell insulating film 130 may be formed between the substrate 100 and the cell conductive line 140, and between the cell element isolation film 105 and the cell conductive line 140.

The cell insulating film 130 may be a single film. However, as shown, the cell insulating film 130 may be embodied as a stack of films including a first cell insulating film 131 and a second cell insulating film 132. For example, the first cell insulating film 131 may include a silicon oxide film, and the second cell insulating film 132 may include a silicon nitride film. However, the present disclosure is not necessarily limited thereto. Unlike what is shown, the cell insulating film 130 may be embodied as a stack of triple films including a silicon oxide film, a silicon nitride film, and a silicon oxide film. However, the present disclosure is not necessarily limited thereto.

The bit-line contact 146 may be disposed between the cell conductive line 140 and the substrate 100. The cell conductive line 140 may be disposed on the bit-line contact 146.

The bit-line contact 146 may be disposed between the bit-line connection portion 103a of the cell active area ACT and the cell conductive line 140. The bit-line contact 146 may electrically connect the cell conductive line 140 and the substrate 100 to each other. The bit-line contact 146 may be connected to the bit-line connection portion 103a.

The bit-line contact 146 may include an upper surface 146US connected to the cell conductive line 140. It is shown that in a direction away from the upper surface 146US of the bit-line contact, a width of the bit-line contact 146 in the first direction DR1 is constant. This is for convenience of illustration and the present disclosure is not necessarily limited thereto.

The bit-line contact 146 may correspond to the direct contact DC. For example, bit-line contact 146 may include a semiconductor material doped with an impurity, a conductive metal silicide, a conductive metal nitride, a conductive metal oxide, a metal, and/or a metal alloy.

In a portion of the cell conductive line 140 where the bit-line contact 146 is formed, the bit-line spacer 150 may be disposed on the substrate 100 and the cell element isolation film 105. The bit-line spacer 150 may be disposed on a sidewall of each of the cell conductive line 140, the cell line capping film 144, and the bit-line contact 146.

In a remaining portion of the cell conductive line 140 where the bit-line contact 146 is not formed, the bit-line spacer 150 may be disposed on the cell insulating film 130. The bit-line spacer 150 may be disposed on a sidewall of each of the cell conductive line 140 and the cell line capping film 144.

The storage contact 120 may be disposed between cell conductive lines 140 adjacent to each other in the first direction DR1. The storage contact 120 may be disposed on each of both opposing sides of the cell conductive line 140. For example, the storage contact 120 may be disposed between the bit-line structures 140ST. The storage contact 120 may be disposed between word-lines WL adjacent to each other in the second direction DR2.

The storage contact 120 may overlap the substrate 100 and the cell element isolation film 105 in an area between adjacent cell conductive lines 140. The storage contact 120 may be connected to the cell active area ACT. For example, the storage contact 120 may be connected to the storage connection portion 103b. In this regard, the storage contact 120 may correspond to the buried contact (BC in FIG. 11).

For example, the storage contact 120 may include a semiconductor material doped with impurities, a conductive silicide compound, a conductive metal nitride, a conductive metal carbide, a conductive metal carbonitride, a conductive metal oxide, and/or a metal.

A storage pad 160 may be disposed on the storage contact 120. The storage pad 160 may be electrically connected to the storage contact 120. The storage pad 160 may be connected to the storage connection portion 103b of the cell active area ACT. In this regard, the storage pad 160 may correspond to the landing pad (LP in FIG. 11).

The storage pad 160 may overlap a portion of an upper surface of the bit-line structure 140ST. For example, the storage pad 160 may include a conductive silicide compound, a conductive metal nitride, a conductive metal carbide, a conductive metal oxide, and/or a metal.

A pad isolation insulating film 180 may be disposed on the storage pad 160 and the bit-line structure 140ST. For example, the pad isolation insulating film 180 may be disposed on the cell line capping film 144.

The pad isolation insulating film 180 may define the storage pad 160 as each of a plurality of isolated areas. The pad isolation insulating film 180 might not cover the upper surface 160US of the storage pad. For example, a vertical level of an upper surface 160US of the storage pad based on the upper surface of the substrate 100 may be equal to a vertical level of an upper surface 180US of the pad isolation insulating film based on the upper surface of the substrate 100.

The pas isolation insulating film 180 includes an insulating material and may electrically insulate the plurality of storage pads 160 from each other. For example, the pad isolation insulating film 180 may include a silicon oxide film, a silicon nitride film, a silicon oxynitride film, a silicon oxycarbonitride film, and/or a silicon carbonitride film. However, the present disclosure is not necessarily limited thereto.

A second etch stop film 195 may be disposed on the upper surface 160US of the storage pad and the upper surface 180US of the pad isolation insulating film. For example, the second etch stop film 195 may correspond to the first etch stop film 25 in FIG. 1, FIG. 4, and FIG. 6 to FIG. 10.

For example, the second etch stop film 195 may include silicon nitride (SiN), silicon carbonitride (SiCN), silicon oxycarbonitride (SiOCN), silicon oxycarbide (SiOC), and/or silicon boron nitride (SiBN).

The data storage pattern DSP may be disposed on the storage pad 160. The data storage pattern DSP is electrically connected to the storage pad 160. A portion of the data storage pattern DSP may be disposed within the second etch stop film 195.

The data storage pattern DSP may include, for example, a capacitor. The data storage pattern DSP includes the lower electrode 191, the capacitor dielectric film 192, and the upper electrode 193.

The first to third lower electrodes supports 50, 60, and 70 may support the lower electrode 191. The first to third lower electrode supports 50, 60, and 70 may be in contact with the lower electrode 191. The lower electrode 191 may include the at least one first bowing area 191_BR1 of the lower electrode.

The descriptions about the lower electrode 191, the capacitor dielectric film 192, and the upper electrode 193 may be substantially the same as those as set forth above using FIGS. 1 to 10, and thus, to the extent that an element is not described in detail with respect to this figure, it may be understood that the element is at least similar to a corresponding element that has been described elsewhere within the present disclosure.

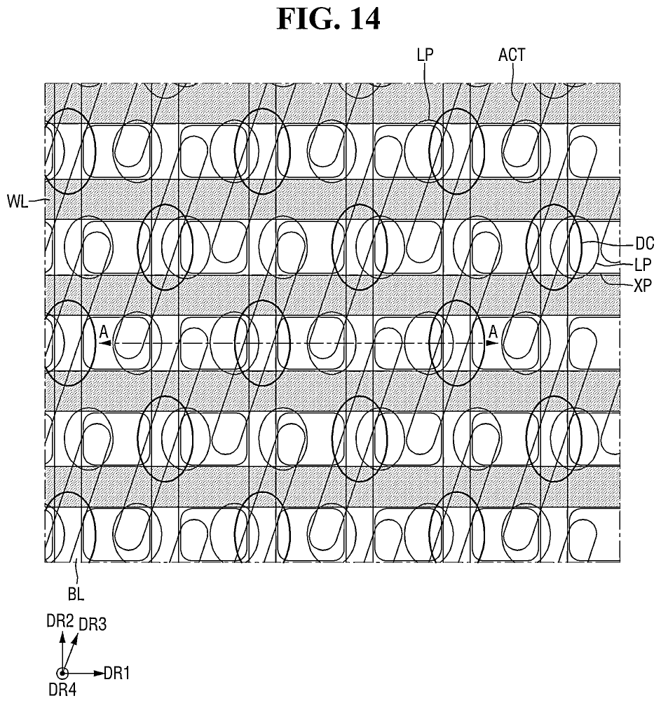

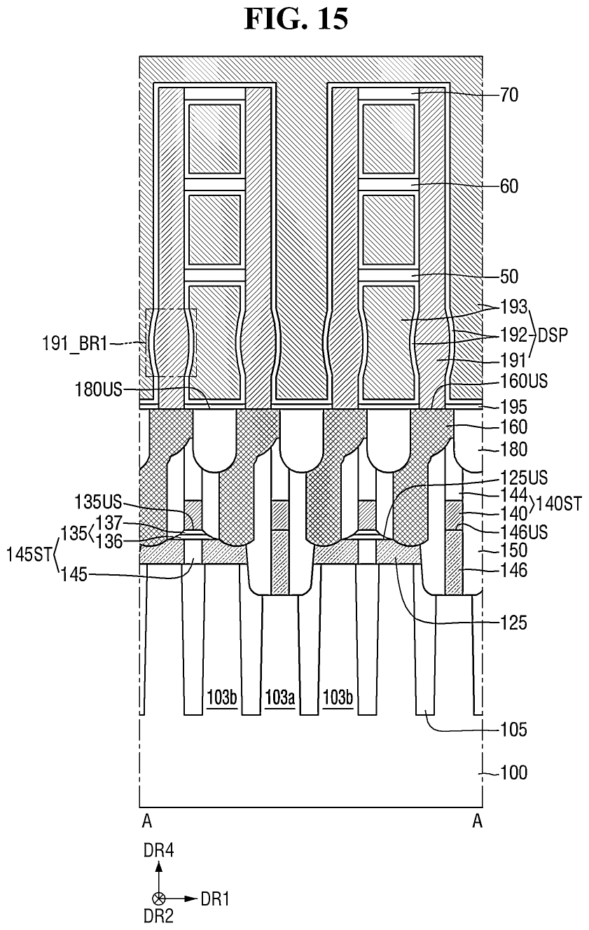

FIG. 14 and FIG. 15 are diagrams illustrating a semiconductor memory device, according to some embodiments. For convenience of description, following description is based on differences thereof from the descriptions set forth above using FIG. 11 to FIG. 13.

For reference, FIG. 14 is a layout of a semiconductor memory device, according to some embodiments. FIG. 15 is a cross-sectional view cut along A-A in FIG. 14.

Referring to FIG. 12, FIG. 14, and FIG. 15, the semiconductor memory device, according to some embodiments, may include a node pad XP disposed on the substrate 100.

The node pad XP may be disposed in place of the buried contact BC in FIG. 11. The node pad XP may be a contact pad that connects the cell active area ACT to the lower electrode 191 of the data storage pattern DSP. The node pad XP may be connected to the storage connection area 103b.

Due to the arrangement structure, a contact area between the node pad XP and the cell active area ACT may be relatively small. Accordingly, a conductive landing pad LP may be introduced to expand a contact area with the cell active area ACT and the lower electrode 191 of the data storage pattern DSP.

As the node pad XP is disposed on each of both opposing end portions of the cell active area ACT, the landing pad LP may be disposed adjacent to each of both opposing ends of the cell active area ACT and overlap at least a portion of the node pad XP. For example, the node pad XP may overlap the cell active area ACT and the cell element isolation film 105 between adjacent word-lines WL and between adjacent bit-lines BL.

The word-line WL may extend across the cell active area ACT between the direct contact DC and the node pad XP. The direct contacts DC may be arranged symmetrically. The node pads XP may be arranged symmetrically. Thus, the direct contacts DC may be arranged in a straight line along each of the first direction DR1 and the second direction DR2. The node pads XP may be arranged in a straight line along each of the first direction DR1 and the second direction DR2.

A node contact pad 125 may be disposed on the substrate 100 and the cell element isolation film 105. The node contact pad 125 may be disposed on the upper surface of the cell element isolation film 105.

A bottom surface of the node contact pad 125 may be disposed on the upper surface of the cell element isolation film 105. The bottom surface of the node contact pad 125 may contact the upper surface of the cell element isolation film 105. For example, an entirety of the node contact pad 125 may be disposed on the upper surface of the substrate 100. In this regard, the node contact pad 125 may correspond to the node pad XP.

Based on the upper surface of the cell element isolation film 105, a vertical level of the upper surface 125US of the node contact pad may be lower than that of the upper surface 146US of the bit-line contact. Based on the upper surface of the cell element isolation film 105, a vertical level of the upper surface 125US of the node contact pad may be lower than that of a bottom surface of the cell conductive line 140.

A contact isolation structure 145ST may space apart from each other node contact pads 125 adjacent to each other in the first direction DR1. The contact isolation structure 145ST may space apart node contact pads 125 adjacent to each other in the second direction DR2 from each other. The contact isolation structure 145ST covers the upper surface 125US of the node contact pad.

The contact isolation structure 145ST may include a contact isolation pattern 145 and an upper cell insulating film 135. The upper cell insulating film 135 may be disposed on the contact isolation pattern 145.

When the node contact pad 125 includes a first node contact pad and a second node contact pad spaced apart from each other in the first direction DR1, the contact isolation pattern 145 may isolate the first node contact pad and the second node contact pad from each other in the first direction DR1. The contact isolation pattern 145 may isolate node contact pads 125 adjacent to each other in the second direction DR2 from each other.

An entirety of the upper surface 125US of the node contact pad might not be in contact with an entirety of the storage pad 160. For example, a width of an interface between the node contact pad 125 and the storage pad 160 in the first direction DR1 may be smaller than a width of the upper surface 125US of the node contact pad in the first direction DR1.

The bit-line spacer 150 may be disposed on the upper surface 125US of the node contact pad.

The upper cell insulating film 135 covers the upper surface 125US of the node contact pad. When the node contact pad 125 includes the first node contact pad and the second node contact pad spaced apart from each other in the first direction DR1, the upper cell insulating film 135 may cover an upper surface of the first node contact pad and an upper surface of the second node contact pad.

An upper surface 135US of the upper cell insulating film may be coplanar with the upper surface 146US of the bit-line contact. For example, based on the upper surface of the cell element isolation film 105, a vertical level of the upper surface 135US of the upper cell insulating film may be equal to a vertical level of the upper surface 146US of the bit-line contact.

The cell conductive line 140 may be disposed on the upper surface of the contact isolation structure 145ST. The cell conductive line 140 may be disposed on the upper surface 135US of the upper cell insulating film. The upper surface of the contact isolation structure 145ST may be the upper surface 135US of the upper cell insulating film. The upper surface of the contact isolation structure 145ST may be coplanar with the bottom surface of the cell conductive line 140.

For example, the contact isolation pattern 145 may include silicon nitride SiN, silicon oxynitride (SiON), silicon oxide SiO₂, silicon carbonitride (SiCN), silicon oxycarbonitride (SiOCN), and/or combinations thereof. The upper cell insulating film 135 may be a single film. However, as shown, the upper cell insulating film 135 may be embodied as a stack of films including a first upper cell insulating film 136 and a second upper cell insulating film 137. For example, the first upper cell insulating film 136 may include a silicon oxide film, and the second upper cell insulating film 137 may include a silicon nitride film. However, the present disclosure is not necessarily limited thereto. It is shown that a width of the upper cell insulating film 135 in the first direction DR1 decreases in a direction away from the substrate 100. However, the present disclosure is not necessarily limited thereto.

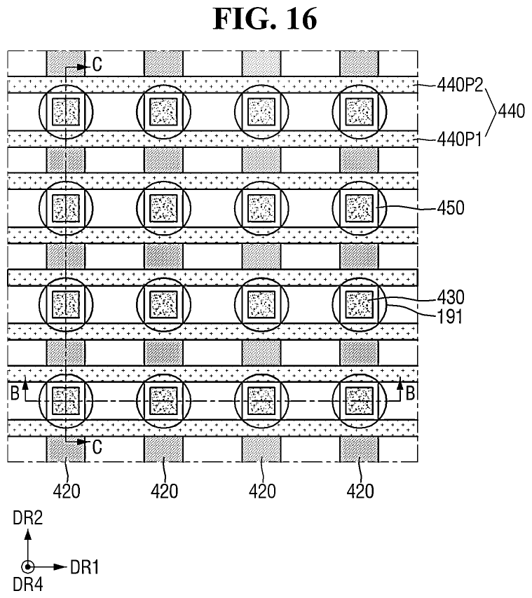

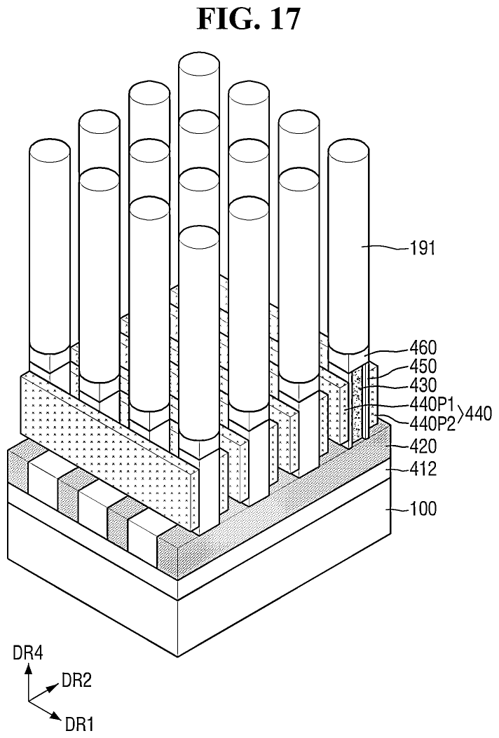

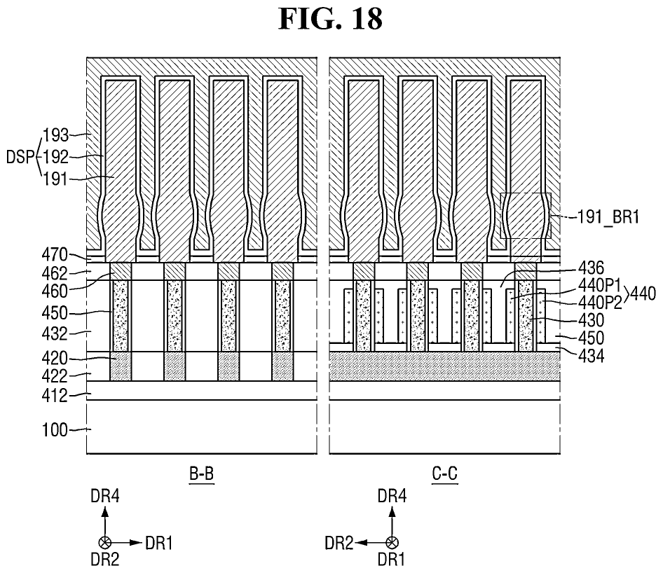

FIG. 16 is a layout diagram illustrating a semiconductor memory device, according to some embodiments. FIG. 17 is a perspective view illustrating a semiconductor memory device, according to some embodiments. FIG. 18 is a cross-sectional view cut along lines B-B and C-C of FIG. 16.

For convenience of illustration, FIG. 18 excludes the first to third lower electrode supports 50, 60, and 70.

Referring to FIGS. 16 to 18, the semiconductor memory device, according to some embodiments, may include the substrate 100, a plurality of first conductive lines 420, a channel layer 430, a gate electrode 440, a gate insulating film 450, and the data storage pattern DSP.

The semiconductor memory device, according to some embodiments, may be a memory device including a vertical channel transistor (VCT). The vertical channel transistor may refer to a structure in which a channel length of the channel layer 430 extends from the substrate 100 primarily along a vertical direction.

A lower insulating layer 412 may be disposed on the substrate 100. The plurality of first conductive lines 420 may be disposed on the lower insulating layer 412 and may be spaced apart from each other in the first direction DR1 and extend primarily in the second direction DR2. A plurality of first insulating patterns 422 may be disposed on the lower insulating layer 412 so as to fill a space between adjacent ones of the plurality of first conductive lines 420. The plurality of first insulating patterns 422 may extend primarily in the second direction DR2. An upper surface of the plurality of first insulating patterns 422 may be position at the same vertical level as that of an upper surface of the plurality of first conductive lines 420. Each of the plurality of first conductive lines 420 may function as a bit-line.

Each of the plurality of first conductive lines 420 may include a semiconductor material doped with impurities, a metal, a conductive metal nitride, a conductive metal silicide, a conductive metal oxide, and/or a combination thereof. For example, each of the plurality of first conductive lines 420 may include polysilicon doped with impurities, Al, Cu, Ti, Ta, Ru, W, Mo, Pt, Ni, Co, TiN, TaN, WN, NON, TiAl, TiAIN, TiSi, TiSN, TaSi, TaSiN, RuTiN, NiSi, CoSi, IrOx, RuOx, and/or a combination thereof, but might not necessarily be limited thereto. Each of the plurality of first conductive lines 420 may include a single layer or multiple layers made of the aforementioned materials. In some embodiments, each of the plurality of first conductive lines 420 may include graphene, carbon nanotube, or a combination thereof.

The channel layer 430 may have a matrix form in which channels are spaced apart from each other in each of the first direction DR1 and the second direction DR2 and are disposed on the plurality of first conductive lines 420, respectively. Each channel of the channel layer 430 may have a first width according to the first direction DR1 and a first vertical dimension according to the fourth direction DR4, wherein the first vertical dimension may be greater than the first width. In this regard, the fourth direction DR4 may intersect the first direction DR1 and the second direction DR2, and may be, for example, a direction perpendicular to the upper surface of the substrate 100. For example, the first vertical dimension may be about 2 to 10 times that of the first width. However, the disclosure is not necessarily limited thereto. A bottom portion of each channel of the channel layer 430 may function as a third source/drain area, while a top portion of each channel of the channel layer 430 may function as a fourth source/drain area. A portion of each channel of the channel layer 430 between the third and fourth source/drain areas may function as a channel area.

In one example, the channel layer 430 may include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. The channel layer 430 may include a single layer or multiple layers made of the oxide semiconductor. In some examples, the channel layer 430 may have a bandgap energy greater than that of silicon. For example, the channel layer 430 may have a bandgap energy of about 1.5 eV to about 5.6 eV. For example, the channel layer 430 may have optimal channel performance when the layer 430 has a bandgap energy of about 2.0 eV to 4.0 eV. For example, the channel layer 430 may be made of a polycrystalline material or an amorphous material, such as silicon, but might not necessarily be limited thereto. In an example, the channel layer 430 may include graphene, carbon nanotubes, or a combination thereof. In an example, the channel layer 430 may include a silicon-based semiconductor material. The channel layer 430 may include a single crystal semiconductor material. For example, the channel layer 430 may include single crystal silicon or single crystal silicon-germanium. However, the present disclosure is not necessarily limited thereto.

The gate electrode 440 may extend in the first direction DR1 and may be formed on both sidewalls of each channel of the channel layer 430. The gate electrode 440 may include a first sub-gate electrode 440P1 facing toward a first sidewall of the channel layer 430, and a second sub-gate electrode 440P2 facing toward a second sidewall opposite to the first sidewall of the channel layer 430. As one channel of the channel layer 430 is disposed between the first sub-gate electrode 440P1 and the second sub-gate electrode 440P2, the semiconductor device may have a dual gate transistor structure. However, the technical idea of the present disclosure is not necessarily limited thereto. For example, the second sub-gate electrode 440P2 may be omitted and thus only the first sub-gate electrode 440P1, facing toward the first sidewall of the channel layer 430, may be formed, so that a single gate transistor structure may be implemented.

The gate electrode 440 may include metal, conductive metal nitride, conductive metal carbonitride, conductive metal carbide, metal silicide, doped semiconductor material, conductive metal oxynitride, and/or the conductive metal oxide. The gate electrode 440 may include, for example, TiN, TaC, TaN, TiSiN, TaSiN, TaTN, TiAlN, TaAlN, WN, Ru, TiAl, TiAlC—N, TiAlC, TiC, TaCN, W, Al, Cu, Co, Ti, Ta, Ni, Pt, Ni-Pt, Nb, NON, NbC, Mo, MON, MoC, WC, Rh, Pd, Ir, Ag, Au, Zn, V, RuTiN, TiSi, TaSi, NiSi, CoSi, IrOₓ, RuOₓ and/or combinations thereof. The present disclosure is not necessarily limited thereto.

The gate insulating film 450 surrounds a sidewall of each channel of the channel layer 430 and may be interposed between each channel of the channel layer 430 and the gate electrode 440. For example, as shown in FIG. 16, an entirety of a sidewall of each channel of the channel layer 430 may be surrounded with the gate insulating film 450, and a portion of a sidewall of the gate electrode 440 may contact the gate insulating film 450. In embodiments, the gate insulating film 450 may extend in an extension direction of the gate electrode 440, for example, the first direction DR1, and only two sidewalls facing toward the gate electrode 440 among all of sidewalls of each channel of the channel layer 430 may contact the gate insulating film 450.

For example, the gate insulating film 450 may include silicon oxide, silicon nitride, silicon oxynitride, and/or a high dielectric constant material having, for example, a higher dielectric constant than that of silicon oxide. The high dielectric constant material may include, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and/or combinations thereof. However, embodiments of the present disclosure are not necessarily limited thereto.

A plurality of second insulating patterns 432 may extend along the second direction DR2 and may be disposed on the plurality of first insulating patterns 422, respectively. Each channel of the channel layer 430 may be disposed between adjacent two second insulating patterns 432 of the plurality of second insulating patterns 432. Further, a first buried layer 434 and a second buried layer 436 may be disposed between two adjacent second insulating patterns 432 and in a space between two adjacent channels of the channel layer 430. The first buried layer 434 may occupy a bottom portion of a space between two adjacent channels of the channel layer 430. The second buried layer 436 may fill a remainder of the space between the two adjacent channels of the channel layer 430 and may be disposed on the first buried layer 434. An upper surface of the second buried layer 436 may be coplanar with an upper surface of the channel layer 430, and the second buried layer 436 may cover an upper surface of the gate electrode 440. Alternatively, each of the plurality of second insulating pattern 432 and each of the plurality of first insulating patterns 422 may constitute a continuous material layer and thus may be monolithic. Alternatively, the second buried layer 436 and the first buried layer 434 may constitute a continuous material layer and thus may be monolithic.

Each capacitor contact 460 may be disposed on each channel of the channel layer 430. Each capacitor contact 460 may vertically overlap each channel of the channel layer 430. Thus, the capacitor contacts 460 may be arranged in a matrix form in which the capacitor contacts 460 are spaced apart from each other in each of the first direction DR1 and the second direction DR2. The capacitor contact 460 may include polysilicon doped with impurities, Al, Cu, Ti, Ta, Ru, W, Mo, Pt, Ni, Co, TiN, TaN, WN, NbN, TiAl, TiAlN, TiSi, TiSN, TaSi, TaSN, RuTN, NiSi, CoSi, IrOx, RuOx, and/or a combination thereof, but might not necessarily be limited thereto. An upper insulating layer 462 may surround a sidewall of each capacitor contact 460 and may be disposed on the plurality of second insulating patterns 432 and the second buried layer 436.

A third etch stop film 470 may be disposed on the upper insulating layer 462. The data storage pattern DSP may be disposed on the third etch stop film 470. The data storage pattern DSP may include the lower electrode 191, the capacitor dielectric film 192, and the upper electrode 193. The lower electrode 191 may extend through the third etch stop film 470 and be electrically connected to the upper surface of the capacitor contact 460.

In illustrative embodiments, the lower electrode 191 may vertically overlap the capacitor contact 460. The lower electrodes 191 may be arranged in a matrix form in which the lower electrodes 191 are spaced apart from each other in each of the first direction DR1 and the second direction DR2. Alternatively, a landing pad may be further disposed between the capacitor contact 460 and the lower electrode 191, and thus, the lower electrodes 191 may be arranged in a hexagonal shape.

The descriptions of the lower electrode 191, the capacitor dielectric film 192, and the upper electrode 193 may be substantially the same as those as set forth above using FIGS. 1 to 10, and thus, to the extent that an element is not described in detail with respect to these figures, it may be understood that the element is at least similar to a corresponding element that has been described elsewhere within the present disclosure.

The descriptions about the first to third lower electrode supports 50, 60 and 70 may be substantially the same as those set forth above using FIGS. 1 to 10.

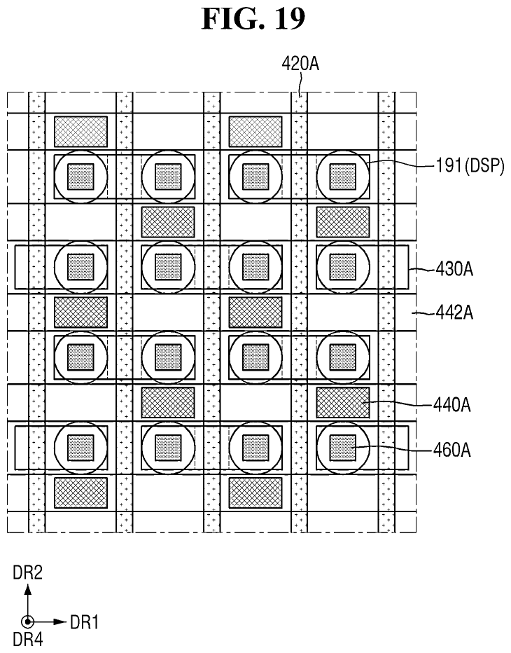

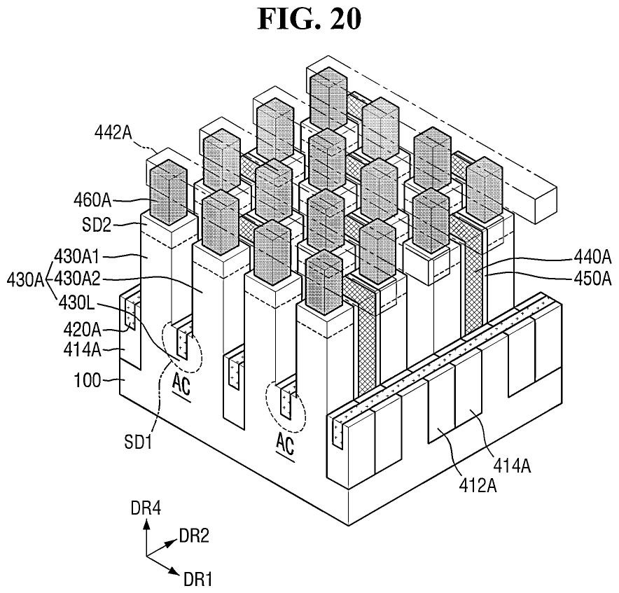

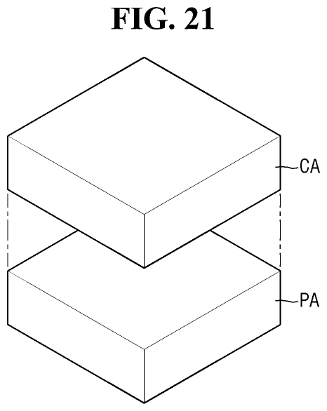

FIG. 19 is a layout diagram illustrating a semiconductor memory device, according to some embodiments. FIG. 20 is a perspective view illustrating a semiconductor memory device, according to some embodiments. FIG. 21 is a diagram illustrating a semiconductor memory device, according to some embodiments.

Referring to FIG. 19 and FIG. 20, the semiconductor memory device, according to some embodiments, may include the substrate 100, a plurality of first conductive line 420A, a channel structure 430A, a contact gate electrode 440A, a plurality of second conductive lines 442A, and the data storage pattern DSP. The semiconductor memory device, according to some embodiments, may be a memory device including a vertical channel transistor (VCT).

A plurality of active areas AC may be defined in the substrate 100 by a first element isolation pattern 412A and a second element isolation pattern 414A. The channel structure 430A may be disposed in each of the active areas AC. The channel structure 430A may include a first active pillar 430A1 and a second active pillar 430A2 extending primarily in a vertical direction, and a connector 430L connected to a bottom portion of the first active pillar 430A1 and a bottom portion of the second active pillar 430A2. A first source/drain area SD1 may be disposed in the connector 430L. A second source/drain area SD2 may be disposed in a top portion of each of the first and second active pillars 430A1 and 430A2. Each of the first active pillar 430A1 and the second active pillar 430A2 may constitute an independent unit memory cell.

The plurality of first conductive lines 420A may extend in a direction intersecting the plurality of active areas AC. For example, the plurality of first conductive lines 420A may extend in the second direction DR2. One first conductive line 420A of the plurality of first conductive lines 420 may be disposed on the connector 430L and between the first active pillar 430A1 and the second active pillar 430A2. One first conductive line 420A may be disposed on the first source/drain area SD1. Another first conductive line 420A, adjacent to said one first conductive line 420A, may be disposed between two channel structures 430A. One first conductive line 420A of the plurality of first conductive lines 420A may function as a common bit-line commonly included in two unit memory cells respectively corresponding to the first active pillar 430A1 and the second active pillar 430A2 respectively disposed on both sides of said one first conductive line 420A.

One contact gate electrode 440A may be disposed between two channel structures 430A adjacent to each other in the second direction DR2. For example, the contact gate electrode 440A may be disposed between the first active pillar 430A1 included in one channel structure 430A and the second active pillar 430A2 of the channel structure 430A adjacent thereto. One contact gate electrode 440A may be shared by the first active pillar 430A1 and the second active pillar 430A2 respectively disposed on both sidewalls thereof. A gate insulating film 450A may be disposed between the contact gate electrode 440A and the first active pillar 430A1 and between the contact gate electrode 440A and the second active pillar 430A2. The plurality of second conductive lines 442A may extend in the first direction DR1. Each second conductive lines 442A may be disposed on an upper surface of each contact gate electrode 440A. Each of the plurality of second conductive lines 442A may function as a word-line of the semiconductor memory device.

A capacitor contact 460A may be disposed on the channel structure 430A. the capacitor contact 460A may be disposed on the second source/drain area SD2. The data storage pattern DSP may be disposed on the capacitor contact 460A.

Referring to FIG. 21, the semiconductor memory device, according to some embodiments, may have a Cell on Peri (COP) structure in which a cell array area CA is disposed on a peripheral structure area PA.

The cell array area CA may include the vertical channel transistor VCT in FIGS. 16 to 20. In the peripheral structure area PA, a sensing transistor, a transfer transistor, a driving transistor, etc. connected to the vertical channel transistor of FIGS. 16 to 20 may be disposed.

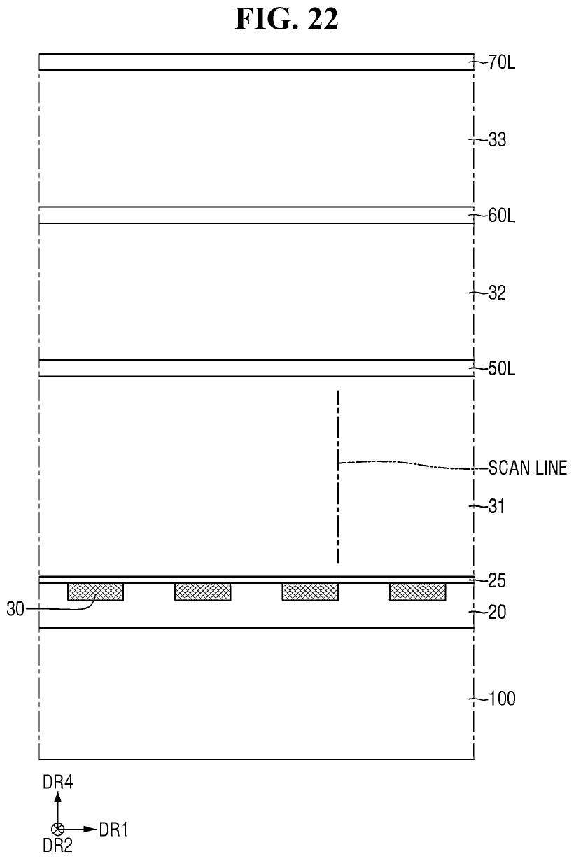

FIGS. 22 to 31 are diagrams of intermediate structures corresponding to intermediate step of a semiconductor memory device manufacturing method according to some embodiments. To the extent that an element is not described in detail with respect to these figures, it may be understood that the element is at least similar to a corresponding element that has been described elsewhere within the present disclosure.

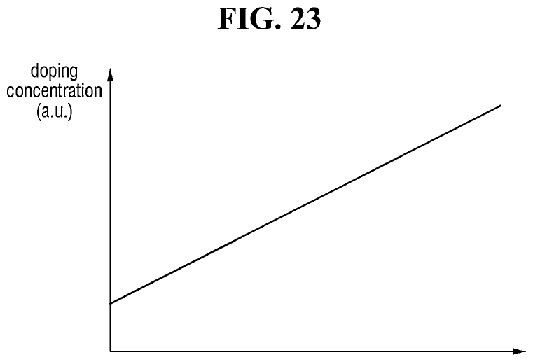

For reference, FIGS. 23 to 27 are diagrams schematically showing a concentration of impurities along a SACN LINE in FIG. 22.

Referring to FIGS. 22 to 27, the interlayer insulating film 20 may be formed on the substrate 100.

The conductive pattern 30 may be formed within the interlayer insulating film 20. The first etch stop film 25 may be formed on the conductive pattern 30 and the interlayer insulating film.

A first mold insulating film 31, a first electrode support film 50L, a second mold insulating film 32, a second electrode support film 60L, a third mold insulating film 33, and a third electrode support film 70L may be formed sequentially on the first etch stop film 25.

Each of the first mold insulating film 31, the second mold insulating film 32, and the third mold insulating film 33 may include silicon oxide, silicon nitride, silicon oxynitride, and/or a low-k material, for example, a material having a dielectric constant (k) that smaller than that of silicon oxide.

Each of the first electrode support film 50L, the second electrode support film 60L, and the third electrode support film 70L may include silicon nitride, silicon carbonitride, silicon boronitride, silicon carbonate, silicon oxynitride, and/or silicon oxycarbonitride. However, the present disclosure is not necessarily limited thereto.

Unlike what is shown, the third electrode support film 70L might not be formed.

Hereinafter, the first mold insulating film 31 is described in more detail. The following description is not necessarily limited to the first mold insulating film 31. For example, the description about the first mold insulating film 31 may be applied to both the second mold insulating film 32 and the third mold insulating film 33.

For example, the first mold insulating film 31 may include silicon oxide. The first mold insulating film 31 may contain impurities.

In FIGS. 23 to 27, the first mold insulating film 31 may contain at least one of a first type impurity or a second type impurity. In one example, the first type impurity may be an n type impurity, while the second type impurity may be a p type impurity. In an example, the first type impurity may be a p type impurity, while the second type impurity may be an n-type impurity.

For example, the p-type impurity may include boron (B) and/or gallium (Ga). The n-type impurity may include phosphorus (P), arsenic (As), antimony (Sb), and/or bismuth (Bi).

In FIGS. 23 to 25, the first mold insulating film 31 may contain either the first type impurity or the second type impurity.

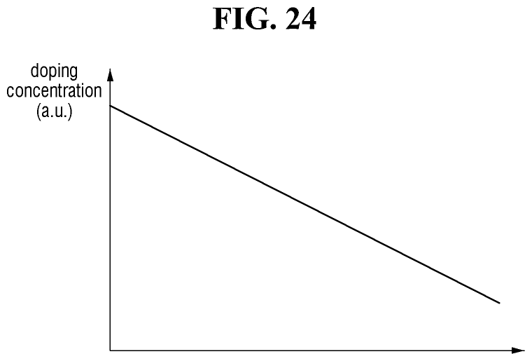

In FIG. 23, a doping concentration of the impurities contained in the first mold insulating film 31 may increase in a direction away from the conductive pattern 30. In FIG. 24, the doping concentration of the impurities contained in the first mold insulating film 31 may decrease in a direction away from the conductive pattern 30.

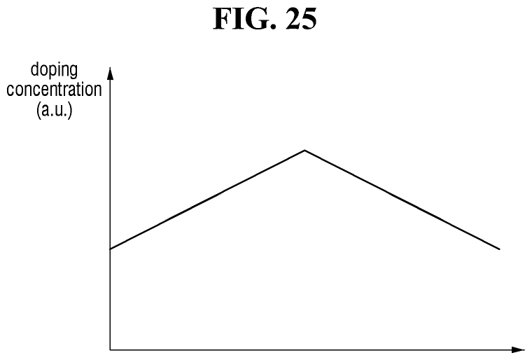

In FIG. 25, the doping concentration of the impurities contained in the first mold insulating film 31 may increase and then decrease in a direction away from the conductive pattern 30. Unlike what is shown, in one example, the doping concentration of the impurities contained in the first mold insulating film 31 may increase and then be constant in a direction away from the conductive pattern 30. In an example, the doping concentration of the impurities contained in the first mold insulating film 31 may increase, then be constant, and then decrease in a direction away from the conductive pattern 30. In an example, the doping concentration of the impurities contained in the first mold insulating film 31 may decrease and then increase in a direction away from the conductive pattern 30. In an example, the doping concentration of the impurities contained in the first mold insulating film 31 may decrease and then be constant in a direction away from the conductive pattern 30. In an example, the doping concentration of the impurities contained in the first mold insulating film 31 may decrease, then be constant, and then increase in a direction away from the conductive pattern 30.

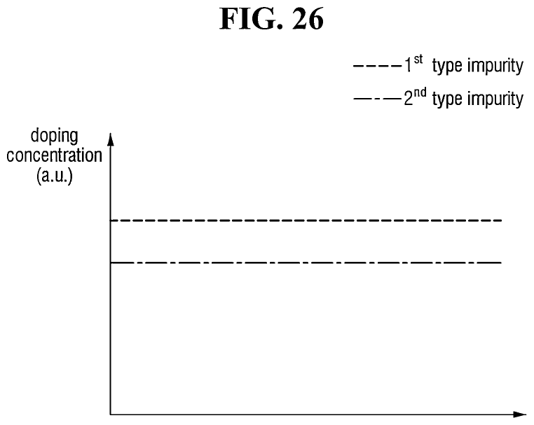

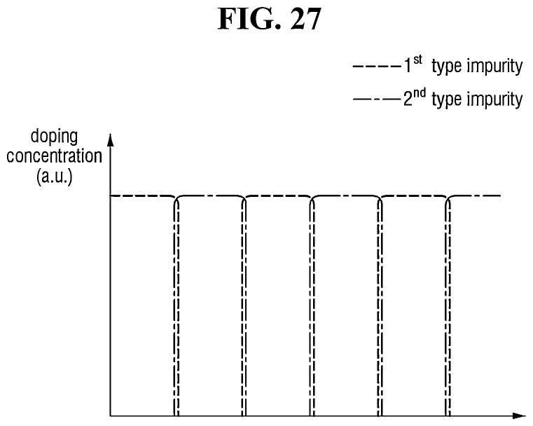

In FIG. 26 and FIG. 27, the first mold insulating film 31 may contain the first type impurity and the second type impurity.

In FIG. 26, the first-type impurity and the second-type impurity may be doped together into the first mold insulating film 31. For example, the second type impurity may be doped into the first mold insulating film 31 doped with the first type impurity.

Although the doping concentration of the first type impurity is shown to be higher than that of the second type impurity, the present disclosure is not necessarily limited thereto. The doping concentration of the first type impurity may be equal to the doping concentration of the second type impurity.

Although each of the doping concentration of the first type impurity and the doping concentration of the second type impurity is shown to be constant, the present disclosure is not necessarily limited thereto. Unlike what is shown, at least one of the doping concentration of the first-type impurity or the doping concentration of the second-type impurity may vary as described using FIGS. 23 to 25.

In FIG. 27, the first mold insulating film 31 may include a first impurity insulating film doped with the first type impurity, and a second impurity insulating film doped with the second type impurity. The first mold insulating film 31 may include the first impurity insulating films and the second impurity insulating films alternately stacked on top of each other.

Unlike what is shown, the first mold insulating film 31 may include the first impurity insulating film and an undoped insulating film that is not doped with an impurity. The first mold insulating film 31 may include the first impurity insulating films and the undoped insulating films that are alternately stacked on top of each other.

It is shown that in each of the first impurity insulating film and the second impurity insulating film, the doping concentration of the impurity is constant. However, this is for convenience of description, and the present disclosure is not necessarily limited thereto. Unlike what is shown, in at least one of the first impurity insulating film or the second impurity insulating film, the doping concentration of the impurity may vary as described using FIGS. 23 to 25.

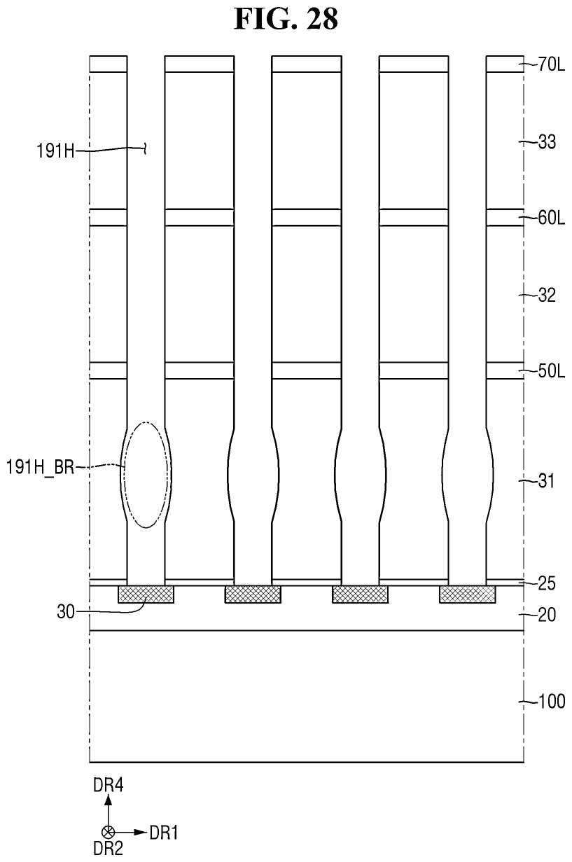

Doping the first mold insulating film 31 with the first type impurity and/or the second type impurity may allow a profile of a lower electrode hole (191H in FIG. 28) to be adjusted in a process of forming the lower electrode hole 191H. For example, a width of the lower electrode hole 191H may be adjusted by adjusting a shape of a sidewall of the lower electrode hole 191H in the process of forming the lower electrode hole 191H.

For example, doping the first mold insulating film 31 with the first type impurity and/or the second type impurity may allow an etch rate of an etching process for forming the lower electrode hole 191H to be increased. Moreover, the width of the lower electrode hole 191H defined during the etching process when the first type impurity is doped into the first mold insulating film 31 may be larger than the width of the lower electrode hole formed in the mold insulating film that does not contain the impurities. Conversely, the width of the lower electrode hole 191H defined during the etching process when the second type impurity is doped into the first mold insulating film 31 may be smaller than the width of the lower electrode hole formed in the mold insulating film that does not contain the impurities. For example, depending on the type of the impurities doped into the first mold insulating film 31, the width of the lower electrode hole 191H may be adjusted. Moreover, the concentration of the impurities contained in the first mold insulating film 31 may be controlled such that the width of the lower electrode hole 191H may be adjusted.

Depending on the type of the impurities contained in the first mold insulating film 31, a by-product produced during the etching process may vary. The by-product produced during the etching process may affect the variation in the width of the lower electrode hole 191H.

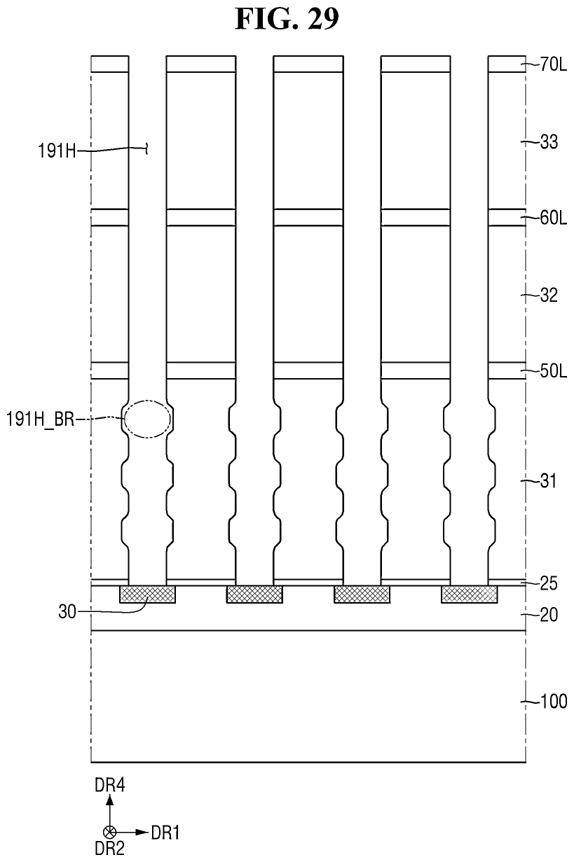

Referring to FIG. 28 and FIG. 29, the lower electrode hole 191H may be formed within the first to third electrode support films 50L, 60L, and 70L and the first to third mold insulating films 31, 32, and 33.

The lower electrode hole 191H may extend through the first etch stop layer 25. The lower electrode hole 191H may expose the conductive pattern 30.

In FIG. 28, the lower electrode hole 191H may include one electrode hole bowing area 191H_BR. In FIG. 29, the lower electrode hole 191H may include a plurality of electrode hole bowing areas 191H_BR.

The lower electrode hole 191H may be formed using a cryogenic etching process. For example, the cryogenic etching process may be carried out at a temperature below 273K based on an absolute temperature.

Following description is made with reference to FIG. 28.

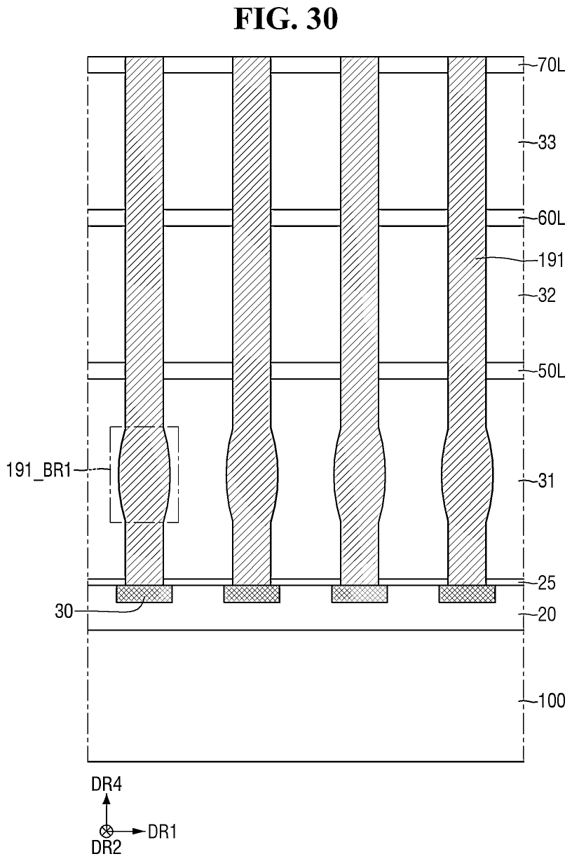

Referring to FIG. 28 and FIG. 30, the lower electrode 191 may be formed on the conductive pattern 30.

The lower electrode 191 may be formed in the lower electrode hole 191H. The lower electrode 191 may include the first bowing area 191_BR1 formed in the electrode hole bowing area 191H_BR.

Unlike what is shown, after forming the lower electrode 191, the third electrode support film 70L may be formed on the lower electrode 191 so as to cover the upper surface of the lower electrode 191.

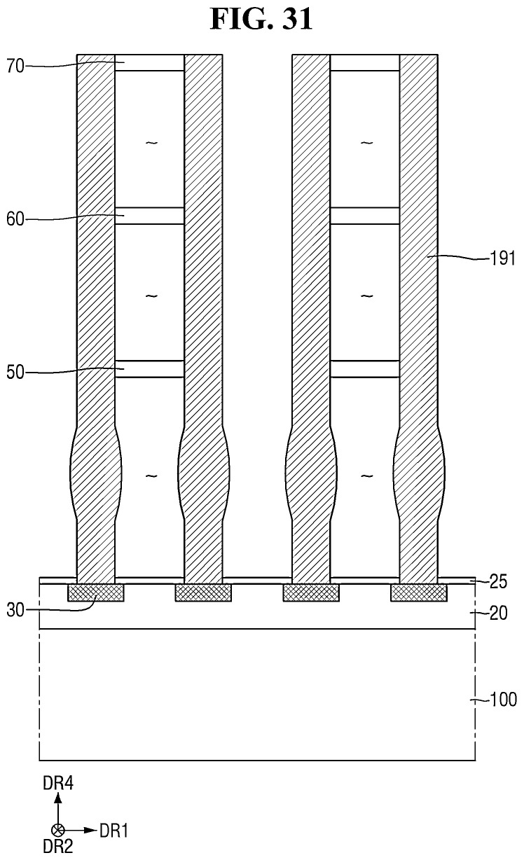

Referring to FIG. 30 and FIG. 31, the third lower electrode support 70 may be formed by patterning the third electrode support film 70L.

The third mold insulating film 33 exposed via the formation of the third lower electrode support 70 may be removed using wet etching.

Subsequently, the second lower electrode support 60 may be formed by patterning the second electrode support film 60L. As the second lower electrode support 60 is formed, the second mold insulating film 32 may be exposed.

Using wet etching, the second mold insulating film 32 may be removed. The second mold insulating film 32 may be removed to expose the first electrode support film 50L.

Subsequently, the first lower electrode support 50 may be formed by patterning the first electrode support film 50L. Thus, the first mold insulating film 31 may be exposed. Subsequently, using wet etching, the first mold insulating film 31 may be removed.

Subsequently, referring to FIG. 1, the capacitor dielectric film 192 and the upper electrode 193 may be formed.

In concluding the detailed description, those skilled in the art will appreciate that many variations and modifications may be made to the preferred embodiments without substantially departing from the principles of the present disclosure. Therefore, the disclosed preferred embodiments of the disclosure may be used in a generic and descriptive sense.

What is claimed is:

1. A semiconductor memory device, comprising:
a conductive pattern disposed on a substrate;
a lower electrode connected to the conductive pattern, and extending primarily in a first direction;
a first lower electrode support spaced apart from the conductive pattern in the first direction, wherein the first lower electrode support is in contact with a sidewall of the lower electrode, and includes an upper surface and a bottom surface opposite to the upper surface in the first direction, wherein the bottom surface of the first lower electrode support faces the conductive pattern;
a capacitor dielectric film disposed on both the lower electrode and the first lower electrode support; and
an upper electrode disposed on the capacitor dielectric film,
wherein the lower electrode includes at least one first bowing area,
wherein a width in a second direction of the lower electrode in the first bowing area of the lower electrode increases and then decreases in a direction away from the conductive pattern, and
wherein the first bowing area of the lower electrode is disposed between the conductive pattern and the first lower electrode support.

2. The semiconductor memory device of claim 1, wherein the first bowing area of the lower electrode does not overlap the first lower electrode support in the second direction.

3. The semiconductor memory device of claim 1, wherein there is no additional lower electrode support disposed between the first lower electrode support and the conductive pattern.

4. The semiconductor memory device of claim 3, wherein the lower electrode includes a plurality of first bowing areas of the lower electrode disposed between the bottom surface of the first lower electrode support and an upper surface of the conductive pattern.

5. The semiconductor memory device of claim 1, further comprising a second lower electrode support disposed between the first lower electrode support and the conductive pattern and in contact with the sidewall of the lower electrode,
wherein the second lower electrode support includes an upper surface and a bottom surface opposite the upper surface in the first direction,
wherein the upper surface of the second lower electrode support faces the bottom surface of the first lower electrode support, and
wherein the first bowing area of the lower electrode is disposed between the bottom surface of the first lower electrode support and the upper surface of the second lower electrode support.

6. The semiconductor memory device of claim 5, wherein the lower electrode includes a plurality of first bowing areas of the lower electrode disposed between the bottom surface of the first lower electrode support and the upper surface of the second lower electrode support.

7. The semiconductor memory device of claim 5, wherein the first bowing area of the lower electrode does not overlap either the first lower electrode support or the second lower electrode support in the second direction.

8. The semiconductor memory device of claim 5, wherein the lower electrode further includes at least one second bowing area disposed under the bottom surface of the second lower electrode support,
wherein a width in the second direction of the lower electrode in the second bowing area of the lower electrode increases and then decreases in a direction away from the bottom surface of the second lower electrode support.

9. The semiconductor memory device of claim 5, wherein a portion of the lower electrode protrudes in the first direction beyond the upper surface of the first lower electrode support.

10. The semiconductor memory device of claim 5, wherein the lower electrode does not include a portion protruding in the first direction beyond the upper surface of the first lower electrode support.

11. The semiconductor memory device of claim 10, wherein the first lower electrode support covers an upper surface of the lower electrode.

12. A semiconductor memory device, comprising:
a conductive pattern disposed on a substrate;
a lower electrode connected to the conductive pattern, and extending primarily in a first direction;
a first lower electrode support spaced apart from the conductive pattern in the first direction and in contact with a sidewall of the lower electrode;
a second lower electrode support disposed between the first lower electrode support and the conductive pattern and in contact with the sidewall of the lower electrode;
a capacitor dielectric film disposed on each of the lower electrode, the first lower electrode support and the second lower electrode support; and
an upper electrode disposed on the capacitor dielectric film,
wherein the lower electrode includes at least one bowing area,
wherein the bowing area of the lower electrode includes a first point, and a second point closer to the conductive pattern than the first point is,
wherein a width in a second direction of the lower electrode at the first point of the lower electrode is smaller than a width in the second direction of the lower electrode at the second point of the lower electrode, and
wherein the bowing area of the lower electrode does not overlap either the first lower electrode support or the second lower electrode support in the second direction.

13. The semiconductor memory device of claim 12, wherein the lower electrode includes a plurality of bowing areas of the lower electrode.

14. The semiconductor memory device of claim 12, wherein the bowing area of the lower electrode is disposed between the conductive pattern and the second lower electrode support, and
wherein there is no additional lower electrode support disposed between the second lower electrode support and the conductive pattern.

15. The semiconductor memory device of claim 12, wherein the bowing area of the lower electrode is disposed between the first lower electrode support and the second lower electrode support.

16. The semiconductor memory device of claim 15, wherein the first lower electrode support includes an upper surface and a bottom surface opposite to the upper surface in the first direction,
wherein the bottom surface of the first lower electrode support faces the conductive pattern, and
wherein the lower electrode does not include a portion protruding in the first direction beyond the upper surface of the first lower electrode support.

17. The semiconductor memory device of claim 12, wherein a width in the second direction of the lower electrode in the bowing area of the lower electrode increases and then decreases in a direction away from the conductive pattern.

18. A semiconductor memory device, comprising:
a substrate including an active area defined by an element isolation film and extended primarily in a first direction, wherein the active area includes a first portion and a second portion defined on each of both opposing sides of the first portion;
a word-line disposed in the substrate and the element isolation film and extending primarily in a second direction different from the first direction, wherein the word-line extends across a portion of the active area disposed between the first portion of the active area and the second portion of the active area;
a bit-line contact connected to the first portion of the active area;
a bit-line disposed on the bit-line contact and connected to the bit-line contact, wherein the bit-line extends primarily in a third direction different from the first direction and the second direction;
a landing pad connected to the second portion of the active area; and
a capacitor,
wherein the capacitor includes:
a lower electrode connected to the landing pad and extending primarily in a fourth direction;
a first lower electrode support spaced apart from the landing pad in the fourth direction and in contact with a sidewall of the lower electrode;
a second lower electrode support disposed between the first lower electrode support and the landing pad and in contact with the sidewall of the lower electrode;
a capacitor dielectric film disposed on the lower electrode, the first lower electrode support and the second lower electrode support; and
an upper electrode disposed on the capacitor dielectric film,
wherein the lower electrode includes at least one bowing area,
wherein a width in the second direction of the lower electrode in the bowing area of the lower electrode increases and then decreases in a direction away from the landing pad, and
wherein the bowing area of the lower electrode does not overlap either the first lower electrode support or the second lower electrode support in the second direction.

19. The semiconductor memory device of claim 18, wherein the bowing area of the lower electrode is disposed between the landing pad and the second lower electrode support, and wherein there is no additional lower electrode support disposed between the second lower electrode support and the landing pad.

20. The semiconductor memory device of claim 18, wherein the bowing area of the lower electrode is disposed between the first lower electrode support and the second lower electrode support,
wherein the first lower electrode support includes an upper surface and a bottom surface opposite to the upper surface in the first direction,
wherein the bottom surface of the first lower electrode support faces the landing pad, and
wherein the lower electrode does not include a portion protruding in the fourth direction beyond the upper surface of the first lower electrode support.
